(19) United States
(12) Patent Application Publication
(10) Pub. No.: US 2026/0371895 A1
(43) Pub. Date: Nov. 19, 2026

(54) DISPLAY DEVICE, ELECTRONIC DEVICE AND METHOD FOR FABRICATING DISPLAY DEVICE

(71) Applicant: Samsung Display Co., Ltd., Yongin-Si (KR)

(72) Inventors: Hyeong Gyu KIM, Yongin-si (KR); Jae Hun SEO, Yongin-si (KR); Jeong Wan HAN, Yongin-si (KR); Hyuncheol KIM, Yongin-si (KR); Sang Ho LEE, Yongin-si (KR)

(21) Appl. No.: 19/405,393

(22) Filed: Dec. 2, 2025

(30) Foreign Application Priority Data
May 19, 2025 (KR) 10-2025-0064662

(51) Int. Cl. H10K 59/80; H10K 59/12; H10K 59/123; H10K 59/131; H10K 102/00

(52) U.S. Cl. CPC H10K 59/80516; H10K 59/1201; H10K 59/123; H10K 59/131; H10K 2102/351

(57) ABSTRACT

A display device includes a substrate, a first pad, a first reflective electrode, a first resonance control layer, a first light emitting stack layer, and a cathode electrode. The substrate includes a first sub-pixel area. The first pad is disposed on the substrate so as to overlap the first sub-pixel area. The first reflective electrode is disposed on the first pad and the first anode electrode is disposed on the first reflective electrode. The first resonance control layer is disposed on the first anode electrode and the first light emitting stack layer is disposed on the first resonance control layer The cathode electrode is disposed on the first light emitting stack layer.

### CROSS-REFERENCE TO RELATED APPLICATION

This application claims priority from Korean Patent Application No. 10-2025-0064662 filed on May 19, 2025 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, an electronic device, and a method for fabricating a display device.

### 2. Description of the Related Art

An organic light emitting display device includes a display element whose luminance is changed by current, for example, an organic light emitting diode.

A head mounted display (HMD) to which the organic light emitting display device is applied is an image display device that is worn on a user’s head in the form of glasses or a helmet and focuses on a distance close to the user’s eyes. The head mounted display may realize virtual reality (VR) or augmented reality (AR).

The head mounted display enlarges and displays an image displayed on a small display device using a plurality of lenses. Therefore, a display device applied to the head mounted display needs to provide a high-resolution image, for example, an image having a resolution of 3000 pixels per inch (PPI) or higher. To this end, organic light emitting diode on silicon (OLEDoS), which is a high-resolution small-sized organic light emitting display device, is used as the display device applied to the head mounted display. The OLEDoS is a device that displays an image by disposing an organic light emitting diode (OLED) on a semiconductor wafer substrate on which a complementary metal oxide semiconductor (CMOS) is disposed.

### SUMMARY

Aspects of the present disclosure provide a display device, an electronic device, and a method for fabricating a display device capable of preventing damage to a reflective electrode during a process.

An embodiment of a display device includes: a substrate including a first sub-pixel area; a first pad disposed on the substrate so as to overlap the first sub-pixel area; a first reflective electrode disposed on the first pad; a first anode electrode disposed on the first reflective electrode; a first resonance control layer disposed on the first anode electrode; a first light emitting stack layer disposed on the first resonance control layer; and a cathode electrode on the first light emitting stack layer.

An embodiment of an electronic device includes a display device including a display screen, wherein the display device includes: a substrate including a first sub-pixel area; a first pad disposed on the substrate so as to overlap the first sub-pixel area; a first reflective electrode disposed on the first pad; a first anode electrode disposed on the first reflective electrode; a first resonance control layer disposed on the first anode electrode; a first light emitting stack layer disposed on the first resonance control layer; and a cathode electrode on the first light emitting stack layer.

An embodiment of a method for fabricating a display device includes: preparing a first substrate having a first sub-pixel area and a second sub-pixel area; forming a first insulating layer on the first substrate, forming a second insulating layer on the first insulating layer, and forming a third insulating layer on the second insulating layer; forming a first trench and a second trench having different depths in the first sub-pixel area and the second sub-pixel area, respectively, in the third insulating layer; forming a first anode electrode in the first trench and forming a second anode electrode in the second trench; forming a preliminary reflective electrode on the first anode electrode, the second anode electrode, and the third insulating layer; forming a first reflective electrode in contact with the first anode electrode and a second reflective electrode in contact with the second anode electrode by patterning the preliminary reflective electrode; forming a preliminary diffusion barrier layer on the first reflective electrode, the second reflective electrode, and the third insulating layer; forming a seed layer on the preliminary diffusion barrier layer; forming a photoresist pattern on the seed layer so as not to overlap the first reflective electrode and the second reflective electrode; forming a first preliminary pad in contact with the first reflective electrode and a second preliminary pad in contact with the second reflective electrode by growing the seed layer using the photoresist pattern as a mask; removing the photoresist pattern; exposing the third insulating layer by removing the preliminary diffusion barrier layer and the seed layer between the first reflective electrode and the second reflective electrode; forming a fourth insulating layer on the third insulating layer; forming a first pad and a second pad having different thicknesses relative to an upper surface of the fourth insulating layer by planarizing the first preliminary pad and the second preliminary pad, respectively; rotating the first substrate by 180 degrees; bringing a first bump and a second bump of a second substrate into contact with the first pad and the second pad, respectively, by attaching the second substrate onto the fourth insulating layer; exposing the third insulating layer by removing the first substrate, the first insulating layer, and the second insulating layer; forming an insulating layer including a first groove overlapping the first anode electrode, a second groove overlapping the second anode electrode, a first resonance control layer disposed between the first anode electrode and the first groove, a second resonance control layer disposed between the second anode electrode and the second groove, and a partition layer disposed between the first sub-pixel area and the second sub-pixel area by patterning the third insulating layer; forming a first light emitting stack layer in the first groove and forming a second light emitting stack layer in the second groove; and forming a cathode electrode on the first light emitting stack layer, the second light emitting stack layer, and the insulating layer.

A display device, an electronic device, and a method for fabricating a display device according to an embodiment may provide the following effects.

First, since the reflective electrode is formed after the formation of the anode electrode, damage to the reflective electrode by hydrogen fluoride may be prevented.

Second, since the display layer and the driving circuit layer are connected through a pad including a copper material, contact resistance between the display layer and the driving circuit layer may be minimized.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view illustrating a display device according to an embodiment;

FIG. 2 is a block diagram illustrating the display device according to an embodiment;

FIG. 3 is an equivalent circuit diagram of a first sub-pixel area according to an embodiment;

FIG. 4 is a cross-sectional view illustrating the display device according to an embodiment;

FIG. 5 is a cross-sectional view of a driving circuit layer of the display device according to an embodiment;

FIGS. 6, 7, 8, 9, 10, 11, 12, 13, 14, 15, 16, 17, 18, 19, 20, 21, 22, 23, 24, 25, 26, and 27 are process cross-sectional views for describing a method for fabricating a display device according to an embodiment;

FIG. 28 is a block diagram of an electronic device according to an embodiment; and

FIGS. 29, 30, and 31 are schematic diagrams of electronic devices according to various embodiments.

### DETAILED DESCRIPTION OF THE EMBODIMENTS

The inventive concept will now be described more fully hereinafter with reference to the accompanying drawings, in which preferred embodiments of the inventive concept are shown. The inventive concept may, however, be embodied in different forms and should not be construed as limited to the embodiments set forth herein. Rather, the embodiments are provided so that this disclosure will be thorough and complete, and will fully convey the scope of the inventive concept to those skilled in the art.

It will also be understood that when a layer is referred to as being "on" another layer or substrate, it can be directly on the other layer or substrate, or intervening layers may also be present. The same reference numbers indicate the same components throughout the specification. In the attached figures, the thickness of layers and regions is exaggerated for clarity.

Although the terms "first", "second", etc. may be used herein to describe various elements, these elements, should not be limited by these terms. These terms may be used to distinguish one element from another element. Thus, a first element discussed below may be termed a second element without departing from teachings of one or more embodiments. The description of an element as a "first" element may not require or imply the presence of a second element or other elements. The terms "first", "second", etc. may also be used herein to differentiate different categories or sets of elements. For conciseness, the terms "first", "second", etc. may represent "first-category (or first-set)", "second-category (or second-set)", etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific exemplary embodiments will be described with reference to the accompanying drawings.

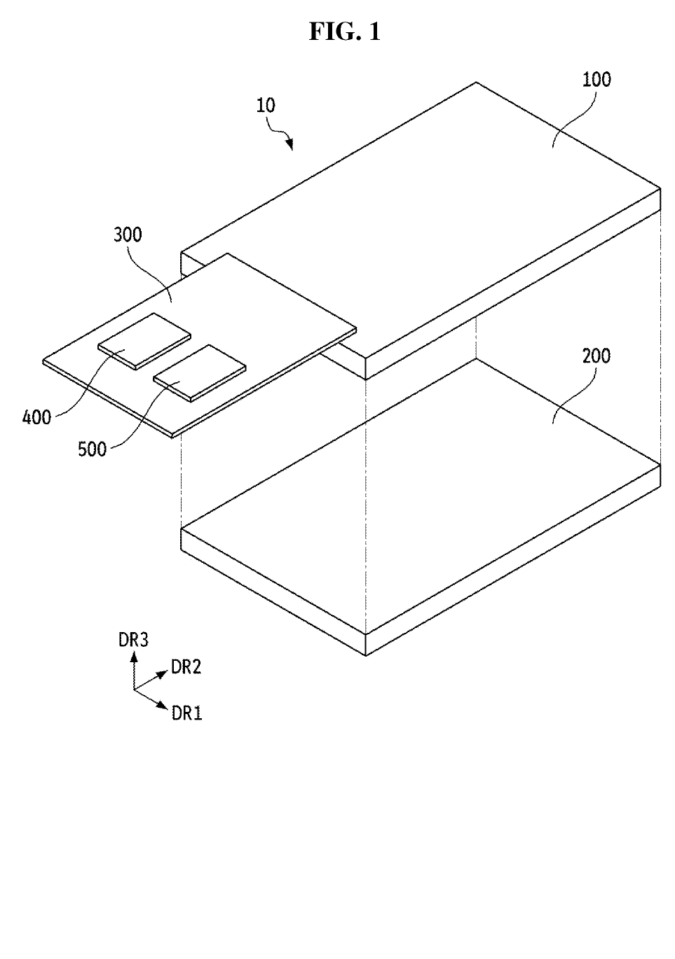

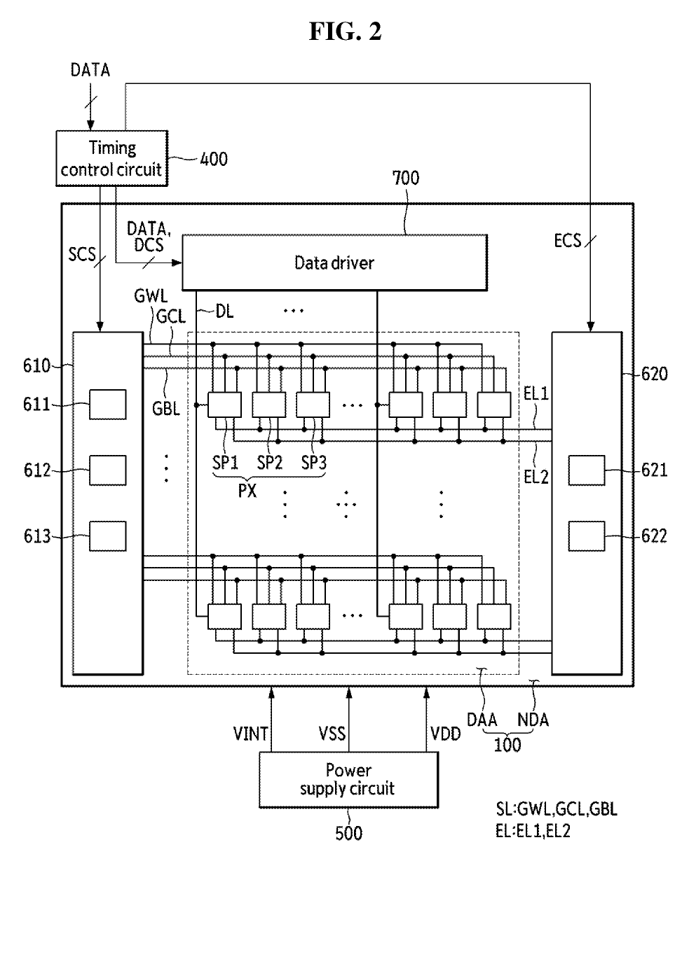

FIG. 1 is an exploded perspective view illustrating a display device according to an embodiment. FIG. 2 is a block diagram illustrating the display device according to an embodiment.

Referring to FIGS. 1 and 2, a display device 10 according to an embodiment is a device displaying a moving image or a still image. The display device 10 according to an embodiment may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to an embodiment may be applied to a display unit of a television, a laptop computer, a monitor, a billboard, or the Internet of Things (IoT). Alternatively, the display device 10 according to an embodiment may be applied to a smart watch, a watch phone, and a head mounted display (HMD) for implementing virtual reality and augmented reality.

The display device according to an embodiment may have a resolution of, for example, 4,000 PPI or more.

The display device 10 according to an embodiment includes a display panel 100, a heat dissipation layer 200, a circuit board 300, a timing control circuit 400, and a power supply circuit 500.

The display panel 100 may be formed in a planar shape similar to a quadrangle. For example, the display panel 100 may have a planar shape similar to a quadrangle having short sides in a first direction DR1 and long sides in a second direction DR2 intersecting the first direction DR1. In the display panel 100, a corner where the short side in the first direction DR1 and the long side in the second direction DR2 meet may be rounded to have a curvature or may be formed at a right angle. The planar shape of the display panel 100 is not limited to the quadrangle, and may be formed similarly to other polygons, circles, or ovals. A planar shape of the display device 10 may follow the planar shape of the display panel 100, but the embodiment of the present specification is not limited thereto.

The display panel 100 includes a plurality of pixel areas PX, a plurality of scan lines SL, a plurality of emission control lines EL, a plurality of data lines DL, a scan driver 610, a light emitting driver 620, and a data driver 700. The display panel 100 may be divided into a display area DAA displaying an image and a non-display area NDA that does not display an image, as illustrated in FIG. 2.

The plurality of pixel areas PX may be disposed in the display area DAA. The plurality of pixel areas PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

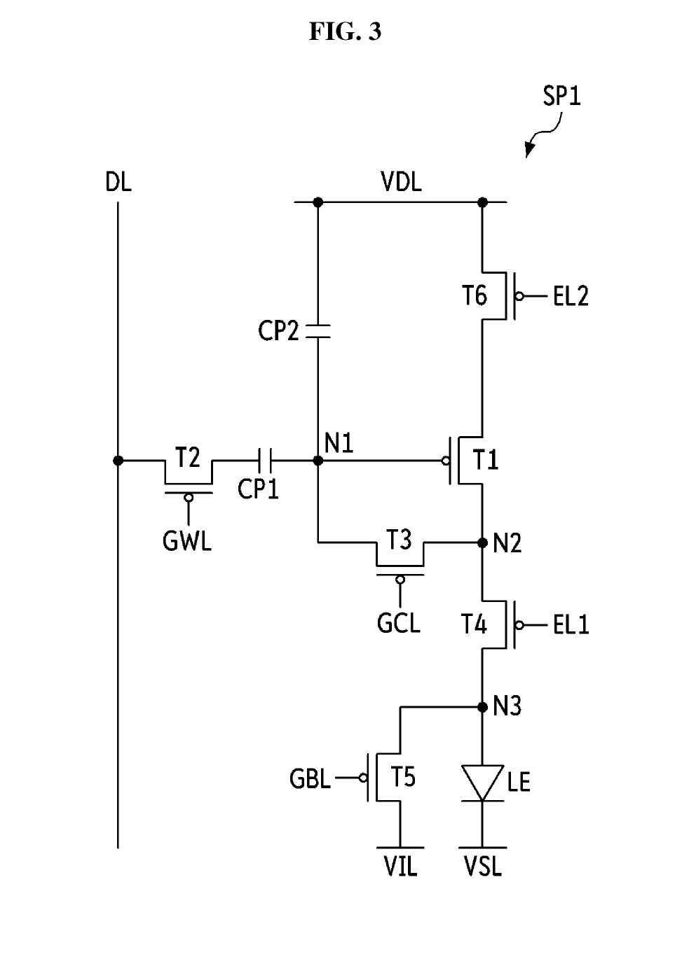

The plurality of pixel areas PX may include a plurality of sub-pixel areas SP1, SP2, and SP3. A plurality of pixel transistors may be disposed in the plurality of sub-pixel areas SP1, SP2, and SP3 as illustrated in FIG. 3. The plurality of pixel transistors may be formed by a semiconductor process and disposed on a semiconductor substrate. For example, the pixel transistors may include a Complementary Metal Oxide Semiconductor (CMOS), but the embodiment of the present specification is not limited thereto.

Each of the plurality of sub-pixel areas SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixel areas SP1, SP2, and SP3 may receive a data voltage of the data line DL according to a write scan signal of the write scan line GWL, and may emit light from a light emitting element according to the data voltage.

The scan driver 610, the light emitting driver 620, and the data driver 700 may be disposed in the non-display area NDA.

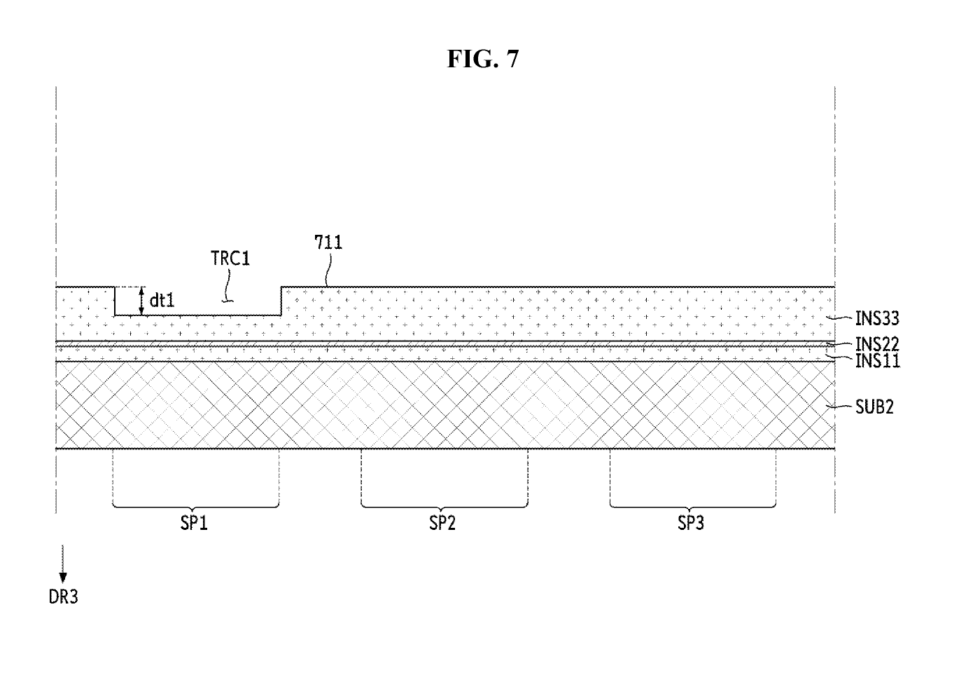

The scan driver 610 includes a plurality of scan transistors, and the light emitting driver 620 includes a plurality of light emitting transistors. The plurality of scan transistors and the plurality of light emitting transistors may be formed through a semiconductor process and may be formed on a semiconductor substrate (SSUB in FIG. 7). For example, the plurality of scan transistors and the plurality of light emitting transistors may include CMOS, but the embodiment of the present specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The light emitting driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed through a semiconductor process and may be formed on a semiconductor substrate (SSUB in FIG. 7). For example, the plurality of data transistors may include CMOS, but the embodiment of the present specification is not limited thereto.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, the sub-pixel areas SP1, SP2, and SP3 may be selected by the write scan signals of the scan driver 610, and the data voltages may be supplied to the selected sub-pixel areas SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, a rear surface of the display panel 100. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

The circuit board 300 may be electrically connected to a plurality of first pads of a first pad portion of the display panel 100 by using a conductive adhesive member such as an anisotropic conductive film. The circuit board 300 may be a flexible printed circuit board or flexible film made of a flexible material. It is illustrated in FIG. 1 that the circuit board 300 is unfolded, but the circuit board 300 may be bent. In this case, one end of the circuit board 300 may be disposed on the rear surface of the display panel 100 or a rear surface of the heat dissipation layer 200. The other end of the circuit board 300 may be connected to the plurality of pads of the pad portion of the display panel 100 by using a conductive adhesive member. One end of the circuit board 300 may be an end opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the light emitting driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply the generated driving voltages to the display panel 100. A description of the first driving voltage VSS, the second driving voltage VDD, and the third driving voltage VINT will be described later with reference to FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the light emitting driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process and may be formed on a semiconductor substrate (SSUB in FIG. 7). For example, the plurality of timing transistors and the plurality of power transistors may include CMOS, but the embodiment of the present specification is not limited thereto. Each of the timing control circuit 400 and the power supply circuit 500 may be disposed between the data driver 700 and the first pad portion.

FIG. 3 is an equivalent circuit diagram of a first sub-pixel area according to an embodiment.

Referring to FIG. 3, the first sub-pixel area SP1 may be connected to the write scan line GWL, the control scan line GCL, the bias scan line GBL, the first emission control line EL1, the second emission control line EL2, and the data line DL. In addition, the first sub-pixel area SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

In the first sub-pixel area SP1, a plurality of transistors T1 to T6, a light emitting element LE, a first capacitor CP1, and a second capacitor CP2 may be disposed.

The light emitting element LE emits light according to a driving current flowing through a channel of a first transistor T1. An amount of light emitted from the light emitting element LE may be proportional to the driving current. The light emitting element LE may be disposed between a fourth transistor T4 and the first driving voltage line VSL. A first electrode of the light emitting element LE may be connected to a drain electrode of the fourth transistor T4, and a second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the present specification is not limited thereto. For example, the light emitting element LE may be an inorganic light emitting element including a first electrode, a second electrode, and an inorganic semiconductor disposed between the first electrode and the second electrode. In this case, the light emitting element LE may be a micro light emitting diode.

The first transistor T1 may be a driving transistor that controls a source-drain current Ids (hereinafter, referred to as “driving current”) flowing between a source electrode and a drain electrode according to a voltage applied to a gate electrode. The first transistor T1 includes a gate electrode connected to a first node N1, a source electrode connected to a drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL and connects one electrode of the first capacitor CP1 to the data line DL. Accordingly, the data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be disposed between the first node N1 and the second node N2. The third transistor T3 is turned on by the write control signal of the write control line GCL and connects the first node N1 to the second node N2. Accordingly, when the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

A fourth transistor T4 may be connected between the second node N2 and a third node N3. The fourth transistor T4 is turned on by the first emission control signal of the first emission control line EL1 and connects the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

A sixth transistor T6 may be disposed between the source electrode of the first transistor T1 and the second driving voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point of the gate electrode of the first transistor T1, the drain electrode of the third transistor T3, the other electrode of the first capacitor CP1, and one electrode of the second capacitor CP2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment of the present specification is not limited thereto. Each of the first to sixth transistors T1 to T6 may be an N-type MOSFET. Alternatively, each of some of the first to sixth transistors T1 to T6 may be a P-type MOSFET, and each of the remaining transistors may be an N-type MOSFET.

It is illustrated in FIG. 3 that the six transistors T1 to T6 and the two capacitors CP1 and CP2 are disposed in the first sub-pixel area SP1, but the equivalent circuit diagram of the first sub-pixel area SP1 is not limited to that illustrated in FIG. 3. For example, the number of transistors and the number of capacitors in the first sub-pixel area SP1 may be variously changed.

In addition, an equivalent circuit diagram of a second sub-pixel area SP2 and an equivalent circuit diagram of a third sub-pixel area SP3 may be substantially the same as the equivalent circuit diagram of the first sub-pixel area SP1 described with reference to FIG. 3. Therefore, the descriptions of the equivalent circuit diagram of the second sub-pixel area SP2 and the equivalent circuit diagram of the third sub-pixel area SP3 are omitted in the present specification.

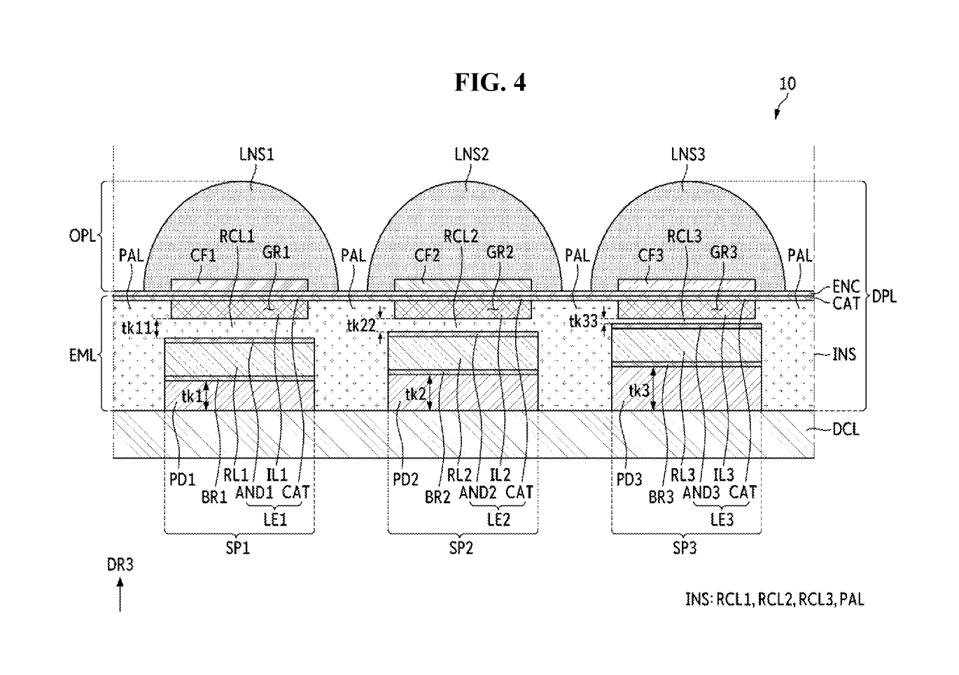

FIG. 4 is a cross-sectional view of the display device 10 according to an embodiment. For example, FIG. 4 may be a cross-sectional view of the display area DAA of the display panel 100 of FIG. 1 described above.

The display device 10 according to an embodiment may include a driving circuit layer DCL and a display layer DPL on the driving circuit layer DCL, as illustrated in FIG. 4.

The driving circuit layer DCL may provide various signals required for the display layer DPL. For example, the driving circuit layer DCL may include the plurality of pixel transistors T1 to T6 as illustrated in FIG. 3 described above.

The display layer DPL may be disposed on the driving circuit layer DCL. The display layer DPL may be electrically connected to the driving circuit layer DCL.

The display layer DPL may include a display element layer EML, an encapsulation layer ENC on the display element layer EML, and an optical layer OPL on the encapsulation layer ENC.

The display element layer EML may include a plurality of pads PD1, PD2, and PD3, a plurality of reflective electrodes RL1, RL2, and RL3, a plurality of anode electrodes AND1, AND2, and AND3 (e.g., first electrodes of the light emitting elements LE1, LE2, and LE3), an insulating layer INS having a plurality of grooves GR1, GR2, and GR3, a plurality of light emitting stack layers IL1, IL2, and IL3, and a cathode electrode CAT (e.g., a second electrode of the light emitting elements LE1, LE2, and LE3).

The plurality of pads PD1, PD2, and PD3 may include a first pad PD1 disposed in the first sub-pixel area SP1, a second pad PD2 disposed in the second sub-pixel area SP2, and a third pad PD3 disposed in the third sub-pixel area SP3. For example, the first pad PD1 may be disposed between the driving circuit layer DCL and a first reflective electrode RL1 to be described later, the second pad PD2 may be disposed between the driving circuit layer DCL and a second reflective electrode RL2 to be described later, and the third pad PD3 may be disposed between the driving circuit layer DCL and a third reflective electrode RL3 to be described later. The first pad PD1pad PD1econd pad PD2, and the third pad PD3 may have different thicknesses. For example, a thickness tk2 of the second pad PD2 may be greater than a thickness tk1 of the first pad PD1pad PD1aller than a thickness tk3 of the third pad PD3. Here, each thickness of each of the pads PD1, PD2, and PD3 may be a size in the direction from the driving circuit layer DCL toward the display layer DPL (e.g., the third direction DR3). The first pad PD1pad PD1 made of a material including copper. The second pad PD2 and the third pad PD3 may each be made of the same material as the first pad PD1pad PD1.

A plurality of reflective electrodes RL1, RL2, and RL3 may be respectively disposed on the plurality of pads PD1, PD2, and PD3. The plurality of reflective electrodes RL1, RL2, and RL3 may include a first reflective electrode RL1 disposed on the first pad PD1 of the first sub-pixel area SP1, a second reflective electrode RL2 disposed on the second pad PD2 of the second sub-pixel area SP2, and a third reflective electrode RL3 disposed on the third pad PD3 of the third sub-pixel area SP3. For example, the first reflective electrode RL1 may be disposed between the first pad PD1 and a first anode electrode AND1 to be described later, the second reflective electrode RL2 may be disposed between the second pad PD2 and a second anode electrode AND2 to be described later, and the third reflective electrode RL3 may be disposed between the third pad PD3 and a third anode electrode AND3 to be described later. The first reflective electrode RL1, the seconRL1eflective electrode RL2, and the third reflective electrode RL3 may have the same thickness. As described above, as the first pad PD1, the second pad PD2, and the third pad PD3 have different thicknesses, heights of upper surfaces of the first to third reflective electrodes RL1 to RL3 respectively disposed on the first to third pads PD1 to PD3 may be different from each other. For example, in the third direction DR3, the upper surface of the second reflective electrode RL2 may be higher than the upper surface of the first reflective electrode RL1 and lower than the upper surface of the third reflective electrode RL3. Here, the upper surface of the first reflective electrode RL1, the upper surface of the second reflective electrode RL2, and the upper surface of the third reflective electrode RL3 may be surfaces that are in contact with the first anode electrode AND1, the second anode electrode AND2, and the third anode electrode AND3, respectively. In addition, the height of the upper surface of each of the reflective electrodes RL1, RL2, and RL3 may be, for example, a distance from the interface between the driving circuit layer DCL and the first to third pads PD1 to PD3 to the upper surface of the corresponding reflective electrode (e.g., a distance in the third direction DR3). The first reflective electrode RL1 may be made of a material including aluminum (Al) or silver (Ag). The second reflective electrode RL2 and the third reflective electrode RL3 may each be made of the same material as the first reflective electrode RL1.

According to an embodiment, additionally, a plurality of diffusion barrier layers BR1, BR2, and BR3 may be further disposed between the plurality of pads PD1, PD2, and PD3 and the plurality of reflective electrodes RL1, RL2, and RL3. For example, a first diffusion barrier layer BR1 may be further disposed between the first pad PD1 and the first reflective electrode RL1, a second diffusion barrier layer BR2 may be further disposed between the second pad PD2 and the second reflective electrode RL2, and a third diffusion barrier layer BR3 may be further disposed between the third pad PD3 and the third reflective electrode RL3. In the third direction DR3, the second diffusion barrier layer BR2 may be higher than the first diffusion barrier layer BR1 and lower than the third diffusion barrier layer BR3. The diffusion barrier layer may be made of a material including any one of titanium (Ti), titanium nitride (TiN), tantalum (Ta), and tantalum nitride (TaN).

A plurality of light emitting elements LE1, LE2, and LE3 may be respectively disposed on the plurality of reflective electrodes RL1, RL2, and RL3. The plurality of light emitting elements LE1, LE2, and LE3 may include a first light emitting element LE1 disposed on the first reflective electrode RL1 of the first sub-pixel area SP1, a second light emitting element LE2 disposed on the second reflective electrode RL2 of the second sub-pixel area SP2, and a third light emitting element LE3 disposed on the third reflective electrode RL3 of the third sub-pixel area SP3.

The first light emitting element LE1 may include a first anode electrode AND1, a first light emitting stack layer IL1, and a cathode electrode CAT. The second light emitting element LE2 may include a second anode electrode AND2, a second light emitting stack layer IL2, and a cathode electrode CAT. The third light emitting element LE3 may include a third anode electrode AND3, a third light emitting stack layer IL3, and a cathode electrode CAT.

A plurality of anode electrodes AND1, AND2, and AND3 may be respectively disposed on the plurality of reflective electrodes RL1, RL2, and RL3. The plurality of anode electrodes AND1, AND3, and AND3 may include a first anode electrode AND1 disposed on the first reflective electrode RL1 of the first sub-pixel area SP1, a second anode electrode AND2 disposed on the second reflective electrode RL2 of the second sub-pixel area SP2, and a third anode electrode AND3 disposed on the third reflective electrode RL3 of the third sub-pixel area SP3. For example, the first anode electrode AND1 may be disposed between the first reflective electrode RL1 and a first resonance control layer RCL1 to be described later, the second anode electrode AND2 may be disposed between the second reflective electrode RL2 and a second resonance control layer RCL2, and the third anode electrode AND3 may be disposed between the third reflective electrode RL3 and a third resonance control layer RCL3. The first anode electrode AND1 may be a transparent conductive electrode. For example, the first anode electrode AND1 may be made of a material including indium-tin-oxide (ITO). Each of the second anode electrode AND2 and the third anode electrode AND3 may be made of the same material as the first anode electrode AND1 described above.

An insulating layer INS including the first resonance control layer RCL1, the second resonance control layer RCL2, and the third resonance control layer RCL3 described above may be disposed on the first anode electrode AND1, the second anode electrode AND2, and the third anode electrode AND3. As the insulating layer INS may further include a partition layer PAL, the partition layer PAL may be formed integrally with the first resonance control layer RCL1, the second resonance control layer RCL2, and the third resonance control layer RCL3. The partition layer PAL may be disposed between adjacent sub-pixel areas SP1, SP2, and SP3. For example, the partition layer PAL may be disposed between adjacent pads PD1, PD2, and PD3 of adjacent sub-pixel areas SP1, SP2, and SP3, between adjacent reflective electrodes RL1, RL2, and RL3 of adjacent sub-pixel areas SP1, SP2, and SP3, between adjacent anode electrodes AND1, AND2, and AND3 of adjacent sub-pixel areas SP1, SP2, and SP3, between adjacent resonance control layers RCL1, RCL2, and RCL3 of adjacent sub-pixel areas SP1, SP2, and SP3, and between adjacent light emitting stack layers IL1, IL2, and IL3 of adjacent sub-pixel areas SP1, SP2, and SP3.

In addition, the insulating layer INS may include a first groove GR1 disposed on the first resonance control layer RCL1 so as to overlap the first resonance control layer RCL1, a second groove GR2 disposed on the second resonance control layer RCL2 so as to overlap the second resonance control layer RCL2, and a third groove GR3 disposed on the third resonance control layer RCL3 so as to overlap the third resonance control layer RCL3. The first groove GR1 may have a shape concavely recessed toward the first resonance control layer RCL1 on the insulating layer INS, the second groove GR2 may have a shape concavely recessed toward the second resonance control layer Rlayer RCL2 insulating layer INS, and the third groove GR3 may have a shape concavely recessed toward the third resonance control layer RCL3 on the insulating layer INS. The insulating layer INS may be made of a material including silicon oxide (SiO₂). For example, the first resonance control layer RCL1, the second resonance control layer Rlayer RCL2hird resonance control layer RCL3, and the partition layer PAL may be made of a material including silicon oxide (SiO₂).

The first resonance control layer RCL1, the second resonance control layer RCL2, and the third resonance control layer RCL3 may have different thicknesses. For example, a thickness tk22 of the second resonance control layer RCL2 may be greater than a thickness tk33 of the third resonance control layer RCL3 and smaller than a thickness tk11 of the first resonance control layer RCL1. As the thicknesses of the resonance control layers RCL1, RCL2, and RCL3 in the respective sub-pixel areas SP1, SP2, and SP3 are different, a distance between the first reflective electrode RL1 and the cathode electrode CAT of the first sub-pixel area SP1, a distance between the second reflective electrode RL2 and the cathode electrode CAT of the second sub-pixel area SP2, and a distance between the third reflective electrode RL3 and the cathode electrode CAT of the third sub-pixel area SP3 may be different from each other. For example, a first resonance distance of the first sub-pixel area SP1, a second resonance distance of the second sub-pixel area SP2, and a third resonance distance of the third sub-pixel area SP3 may be different from each other. In other words, the sub-pixel areas providing light of different colors may each have different resonant distances. Therefore, a light emission efficiency may be increased in each of the first to third sub-pixel areas SP1, SP2, and SP3.

A plurality of light emitting stack layers IL1, IL2, and IL3 may be respectively disposed on the plurality of resonance control layers RCL1, RCL2, and RCL2. The plurality of light emitting stack layers IL1, IL2, and IL3 may include a first light emitting stack layer IL1 disposed on the first resonance control layer RCL1 of the first sub-pixel area SP1, a second light emitting stack layer IL2 disposed on the second resonance control layer RCL2 of the second sub-pixel area SP2, and a third light emitting stack layer IL3 disposed on the third resonance control layer RCL3 of the third sub-pixel area SP3. For example, the first light emitting stack layer IL1 may be disposed between the first resonance control layer RCL1 and the cathode electrode CAT, the second light emitting stack layer IL2 may be disposed between the second resonance control layer RCL2 and the cathode electrode CAT, and the third light emitting stack layer IL3 may be disposed between the third resonance control layer RCL3 and the cathode electrode CAT. In this case, the first light emitting stack layer IL1 may be disposed within the first groove GR1 of the insulating layer INS, the second light emitting stack layer Ilayer IL2 disposed within the second groove GR2 of the insulating layer INS, and the third light emitting stack layer IL3 may be disposed within the third groove GR3 of the insulating layer INS.

The first light emitting stack layer IL1 may include a plurality of stack layers sequentially stacked along the third direction DR3. For example, the first light emitting stack layer IL1 may have a three-tandem structure including a first stack layer, a second stack layer on the first stack layer, and a third stack layer on the second stack layer. Here, the second stack layer may be disposed between the first stack layer and the third stack layer. The embodiment of the present specification is not limited thereto. For example, the first light emitting stack layer IL1 may also have a two-tandem structure including two stack layers.

In the three-tandem structure, the first stack layer, the second stack layer, and the third stack layer of the first light emitting stack layer IL1 may provide light of different colors (or wavelengths). For example, one of the first stack layer, the second stack layer, and the third stack layer may provide light of a first color (e.g., green), another of the first stack layer, the second stack layer, and the third stack layer may provide light of a second color (e.g., red), and the other of the first stack layer, the second stack layer, and the third stack layer may provide light of a third color (e.g., blue).

The first stack layer of the first light emitting stack layer IL1 may have a structure in which a first hole transporting layer, a first organic light emitting layer, and a first electron transporting layer are sequentially stacked. The second stack layer of the first light emitting stack layer IL1 may have a structure in which a second hole transporting layer, a second organic light emitting layer, and a second electron transporting layer are sequentially stacked. The third stack layer of the first light emitting stack layer IL1 may have a structure in which a third hole transporting layer, a third organic light emitting layer, and a third electron transporting layer are sequentially stacked. Here, the first organic light emitting layer, the second organic light emitting layer, and the third organic light emitting layer may provide light of different colors (or wavelengths). For example, one of the first organic light emitting layer, the second organic light emitting layer, and the third organic light emitting layer may provide light of a first color (e.g., green), another of the first organic light emitting layer, the second organic light emitting layer, and the third organic light emitting layer may provide light of a second color (e.g., red), and the other of the first organic light emitting layer, the second organic light emitting layer, and the third organic light emitting layer may provide light of a third color (e.g., blue).

A first charge generating layer for supplying charges to the second stack layer and supplying electrons to the first stack layer may be disposed between the first stack layer and the second stack layer. The first charge generating layer may include an n-type charge generating layer that supplies electrons to the first stack layer and a p-type charge generating layer that supplies holes to the second stack layer. The n-type charge generating layer may include a dopant of a metallic material.

A second charge generating layer for supplying charges to the third stack layer and supplying electrons to the second stack layer may be disposed between the second stack layer and the third stack layer. The second charge generating layer may include an n-type charge generating layer that supplies electrons to the second stack layer and a p-type charge generating layer that supplies holes to the third stack layer.

The second light emitting stack layer IL2 and the third light emitting stack layer IL3 may each have the same structure as the first light emitting stack layer IL1 described above. For example, the second light emitting stack layer IL2 may include a first stack layer, a second stack layer, and a third stack layer stacked along the third direction DR3, and similarly, the third light emitting stack layer IL3 may include a first stack layer, a second stack layer, and a third stack layer stacked along the third direction DR3.

The first light emitting stack layer IL1, the second light emitting stack layer IL2, and the third light emitting stack layer IL3 may be separated from each other by the partition layer PAL of the insulating layer INS. In other words, the first light emitting stack layer IL1, the second light emitting stack layer IL2, and the third light emitting stack layer IL3 may be separated from each other by the partition layer PAL defining the first groove GR1, the second groove GR2, and the third groove GR3. Accordingly, the first stack layer of the first light emitting stack layer IL1, the first stack layer of the second light emitting stack layer IL2, and the first stack layer of the third light emitting stack layer IL3 may be separated from each other, the second stack layer of the first light emitting stack layer Ilayer IL1econd stack layer of the second light emitting stack layer IL2, and the second stack layer of the third light emitting stack layer IL3 may be separated from each other, the first charge generating layer of the first light emitting stack layer Ilayer IL1irst charge generating layer of the second light emitting stack layer IL2, and the first charge generating layer of the third light emitting stack layer IL3 may be separated from each other, and the second charge generating layer of the first light emitting stack layer Ilayer IL1econd charge generating layer of the second light emitting stack layer IL2, and the second charge generating layer of the third light emitting stack layer IL3 may be separated from each other.

The cathode electrode CAT may be disposed on the first light emitting stack layer IL1, the second light emitting stack layer IL2, the third light emitting stack layer IL3, and the insulating layer INS. For example, the cathode electrode CAT may be disposed on the third stack layer of the first light emitting stack layer IL1, the third stack layer of the second light emitting stack layer IL2, the third stack layer of the third light emitting stack layer IL3, and the partition layer PAL of the insulating layer INS. The cathode electrode CAT may be disposed on each third stack layer of each light emitting stack layer without being disconnected by the partition layer PAL. The cathode electrode CAT may include a semi-transmissive conductive material such as magnesium (Mg), silver (Ag), or an alloy of magnesium (Mg) and silver (Ag). In this case, light emission efficiency may be increased in each of the first to third sub-pixel areas SP1, SP2, and SP3 by micro cavities.

The encapsulation layer ENC may be disposed on the display element layer EML. The encapsulation layer ENC may include at least one inorganic layer to prevent oxygen or moisture from permeating into the display element layer EML. For example, the encapsulation layer ENC may include a first inorganic encapsulation layer, an organic encapsulation organic layer, and a second inorganic encapsulation layer. In this case, the organic encapsulation layer may be disposed between the first inorganic encapsulation layer and the second inorganic encapsulation layer.

The optical layer may be disposed on the encapsulation layer ENC. The optical layer OPL may include a plurality of color filters CF1, CF2, and CF3 and a plurality of lenses LNS.

The plurality of color filters CF1, CF2, and CF3 may include a first color filter CF1, a second color filter CF2, and a third color filter CF3. The first to third color filters CF1, CF2, and CF3 may be disposed on the encapsulation layer ENC.

The first color filter CF1 may be disposed on the encapsulation layer ENC to overlap the first light emitting stack layer IL1 (or the first groove GR1 of the insulating layer INS) of the first sub-pixel area SP1. The first color filter CF1 may transmit first light (e.g., light in a green wavelength band). For example, the first color filter CF1 may transmit the first light among light emitted from the first light emitting stack layer IL1 of the first groove GR1.

The second color filter CF2 may be disposed on the encapsulation layer ENC to overlap the second light emitting stack layer IL2 (or the second groove GR2 of the insulating layer INS) of the second sub-pixel area SP2. The second color filter CF2 may transmit second light (e.g., light in a red wavelength band). For example, the second color filter CF2 may transmit the second light among light emitted from the second light emitting stack layer IL2 of the second groove GR2.

The third color filter CF3 may be disposed on the encapsulation layer ENC to overlap the third light emitting stack layer IL3 (or the third groove GR3 of the insulating layer INS) of the third sub-pixel area SP3. The third color filter CF3 may transmit third light (e.g., light in a blue wavelength band). For example, the third color filter CF3 may transmit the third light among light emitted from the third light emitting stack layer IL3 of the third groove GR3.

Each of the plurality of lenses LNS1, LNS2, and LNS3 may be disposed on each of the first color filter CF1, the second color filter CF2, and the third color filter CF3. Each of the plurality of lenses LNS1, LNS2, and LNS3 may be a structure for increasing a ratio of light directed to the front of the display device 10. It is illustrated that each of the plurality of lenses LNS1, LNS2, and LNS3 has a cross-sectional shape that is convex in an upward direction, but the embodiment of the present specification is not limited thereto.

A first lens LNS1 may be disposed on the first color filter CF1 and the encapsulation layer ENC to overlap the first color filter CF1 and the first light emitting stack layer IL1 (or the first groove GR1 of the insulating layer INS) of the first sub-pixel area SP1.

A second lens LNS2 may be disposed on the second color filter CF2 and the encapsulation layer ENC to overlap the second color filter CF2 and the second light emitting stack layer IL2 (or the second groove GR2 of the insulating layer INS) of the second sub-pixel area SP2.

A third lens LNS3 may be disposed on the third color filter CF3 and the encapsulation layer ENC to overlap the third color filter CF3 and the third light emitting stack layer IL3 (or the third groove GR3 of the insulating layer INS) of the third sub-pixel area SP3.

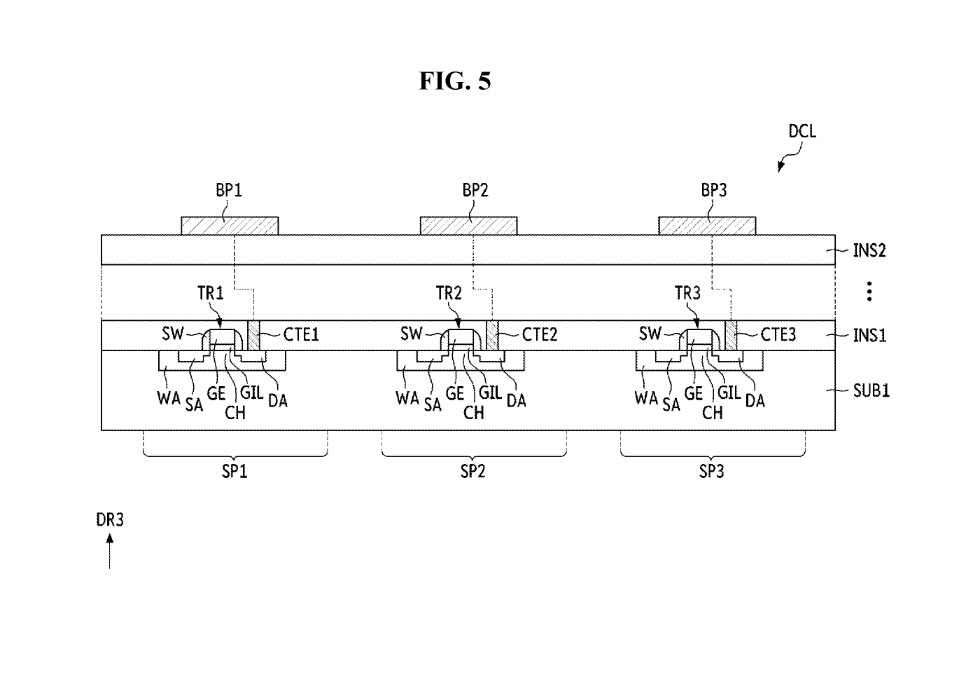

FIG. 5 is a cross-sectional view of a driving circuit layer DCL of the display device 10 according to an embodiment. For example, FIG. 5 may be a cross-sectional view of the driving circuit layer DCL of FIG. 4 described above.

As illustrated in FIG. 5, the driving circuit layer DCL may include a substrate SUB1, a plurality of transistors TR1, TR2, and TR3 on the substrate SUB1, a plurality of insulating layers INS1 and INS2 on the transistors TR1, TR2, and TR3, and a plurality of bumps BP1, BP2, and BP3 on the plurality of insulating layers INS1 and INS2.

The substrate SUB1 may be a silicon substrate, a germanium substrate, or a silicon-germanium substrate. The substrate SUB1 may be a substrate (e.g., a wafer) doped with first-type impurities. A plurality of well areas WA may be disposed in an upper surface of the substrate SUB1. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the plurality of well areas WA may include a source area SA corresponding to a source electrode of each of the pixel transistors TR1, TR2, and TR3, a drain area DA corresponding to a drain electrode thereof, and a channel area CH disposed between the source area SA and the drain area DA.

A first transistor TR1 of the first sub-pixel area SP1, a second transistor TR2 of the second sub-pixel area SP2, and a third transistor TR3 of the third sub-pixel area SP3 may be disposed on the substrate SUB1.

The first transistor TR1, the second transistor TR2, and the third transistor TR3 may each include a gate electrode GE, a source area SA, a drain area DA, and a channel area CH.

A gate insulating layer GIL may be disposed between each gate electrode GE and each well area WA. A side insulating layer SW may be disposed on a side surface of each gate electrode GE.

Each source area SA and each drain area DA may be an area doped with first-type impurities. Each gate electrode GE may overlap the well area WA in the third direction DR3, which is a thickness direction of the substrate SUB1. Each channel area CH may overlap each gate electrode GE in the third direction DR3. Each source area SA may be disposed on one side of each gate electrode GE, and each drain area DA may be disposed on the other side of each gate electrode GE.

The drain area DA of the first transistor TR1 may be connected to a first bump BP1 through a first connection electrode CTE1, the drain area DA of the second transistor TR2 may be connected to a second bump BP2 through a second connection electrode CTE2, and the drain area DA of the third transistor TR3 may be connected to a third bump BP3 through a third connection electrode CTE3.

The first bump BP1 of the driving circuit layer DCL may be disposed on the first transistor TR1 of the first sub-pixel area SP1. For example, the first bump BP1 of the driving circuit layer DCL may be disposed between the second insulating layer INS2 and the first pad PD1 of the display layer DPL. The first bump BP1 may be connected to the first pad PD1. For example, an upper surface of the first bump BP1 may be in contact with (or in direct contact with) a lower surface of the first pad PD1. Accordingly, a first signal (e.g., a first data voltage) from the first transistor TR1 may be transmitted to the first pad PD1 through the first connection electrode CTE1 and the first bump BP1. The first signal transmitted to the first pad PD1 may be supplied to the first light emitting stack layer IL1 through the first reflective electrode RL1 and the first anode electrode AND1. For example, an electric field may be generated around the first anode electrode AND1 by the first signal transmitted to the first anode electrode AND1, and the organic light emitting layer of the first light emitting stack layer IL1 may emit light by such an electric field.

The second bump BP2 of the driving circuit layer DCL may be disposed on the second transistor TR2 of the second sub-pixel area SP2. The second bump BP2 of the driving circuit layer DCL may be disposed between the second insulating layer INS2 and the second pad PD2 of the display layer DPL. The second bump BP2 may be connected to the second pad PD2 of the display layer DPL. For example, an upper surface of the second bump BP2 may be in contact with (or in direct contact with) a lower surface of the second pad PD2. Accordingly, a second signal (e.g., a second data voltage) from the second transistor TR2 may be transmitted to the second pad PD2 through the second connection electrode CTE2 and the second bump BP2. The second signal transmitted to the second pad PD2 may be supplied to the second light emitting stack layer IL2 through the second reflective electrode RL2 and the second anode electrode AND2. For example, an electric field may be generated around the second anode electrode AND2 by the second signal transmitted to the second anode electrode AND2, and the organic light emitting layer of the second light emitting stack layer IL2 may emit light by such an electric field.

The third bump BP3 of the driving circuit layer DCL may be disposed on the third transistor TR3 of the third sub-pixel area SP3. The third bump BP3 of the driving circuit layer DCL may be disposed between the second insulating layer INS2 and the third pad PD3 of the display layer DPL. The third bump BP3 may be connected to the third pad PD3. For example, an upper surface of the third bump BP3 may be in contact with (or in direct contact with) a lower surface of the third pad PD3. Accordingly, a third signal (e.g., a third data voltage) from the third transistor TR3 may be transmitted to the third pad PD3 through the third connection electrode CTE3 and the third bump BP3. The third signal transmitted to the third pad PD3 may be supplied to the third light emitting stack layer IL3 through the third reflective electrode RL3 and the third anode electrode AND3. For example, an electric field may be generated around the third anode electrode AND3 by the third signal transmitted to the third anode electrode AND3, and the organic light emitting layer of the third light emitting stack layer IL3 may emit light by such an electric field.

The first bump BP1 may be made of a material including copper. The second bump BP2 and the third bump BP3 may each be made of the same material as the first bump BP1.

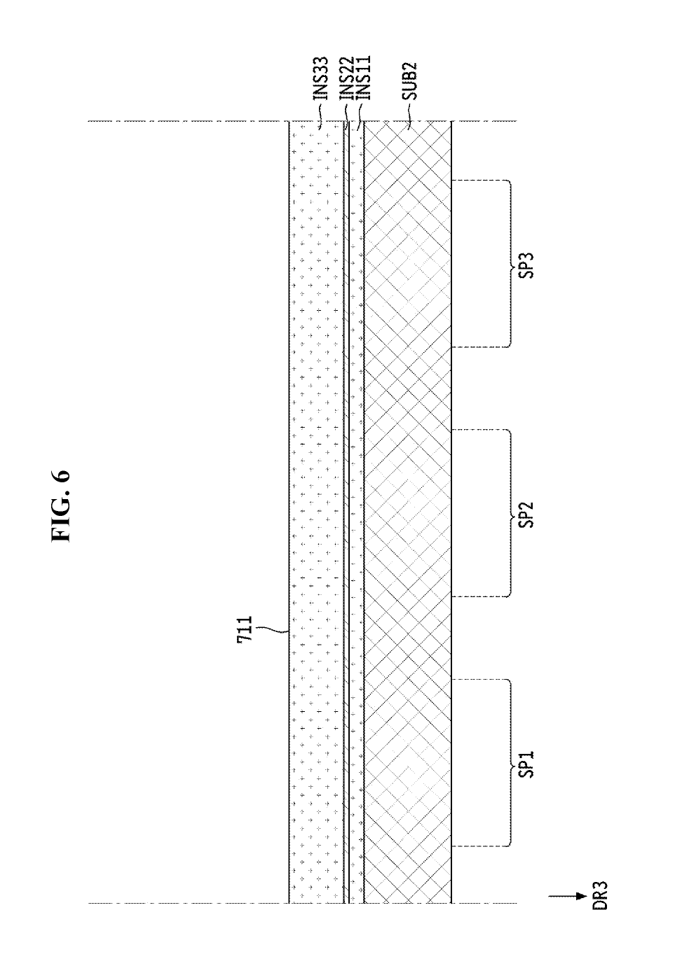

FIGS. 6, 7, 8, 9, 10, 11, 12, 13, 14, 15, 16, 17, 18, 19, 20, 21, 22, 23, 24, 25, 26, and 27 are process cross-sectional views for describing a method for fabricating a display device 10 according to an embodiment. For example, FIGS. 6-27 may be process cross-sectional views for describing a method for fabricating the display device 10 of FIG. 4 described above.

First, as illustrated in FIG. 6, a substrate SUB2 (hereinafter, referred to as a second substrate SUB2) having a first sub-pixel area SP1, a second sub-pixel area SP2, and a third sub-pixel area SP3 may be prepared. The second substrate SUB2 may be a silicon substrate, a germanium substrate, or a silicon-germanium substrate. The second substrate SUB2 may be a wafer. For example, the second substrate SUB2 may be a substrate (e.g., a wafer) doped with first-type impurities.

Next, as illustrated in FIG. 6, a first insulating layer INS11 may be formed on the second substrate SUB2, then a second insulating layer INS22 may be formed on the first insulating layer INS11, and then a third insulating layer INS33 may be formed on the second insulating layer INS22. The first insulating layer INS11 may be made of a material including silicon oxide (SiO₂), the second insulating layer INS22 may be made of a material including silicon nitride (SiNₓ), and the third insulating layer INS33 may be made of the same material as the first insulating layer INS11. For example, the third insulating layer INS33 may be made of a material including silicon oxide (SiO₂).

Next, as illustrated in FIG. 7, the third insulating layer INS33 of the first sub-pixel area SP1 may be removed by patterning the third insulating layer INS33 through a photolithography process. Accordingly, a first trench TRC1 overlapping the first sub-pixel area SP1 may be formed.

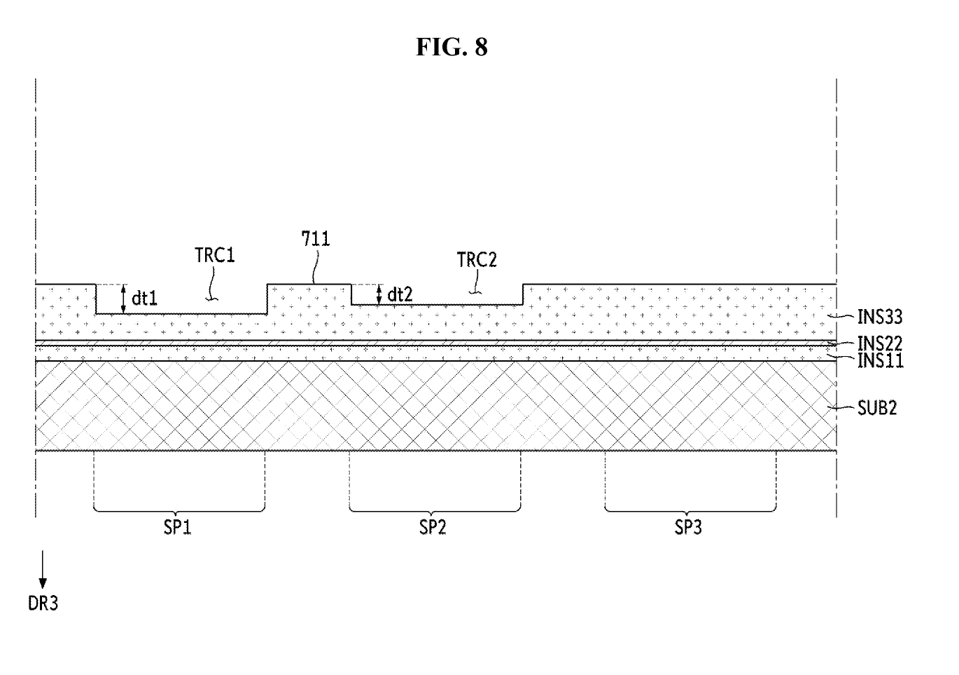

Next, as illustrated in FIG. 8, the third insulating layer INS33 of the second sub-pixel area SP2 may be removed by patterning the third insulating layer INS33 (e.g., the third insulating layer INS33 including the first trench TRC1) through a photolithography process. Accordingly, a second trench TRC2 overlapping the second sub-pixel area SP2 may be formed.

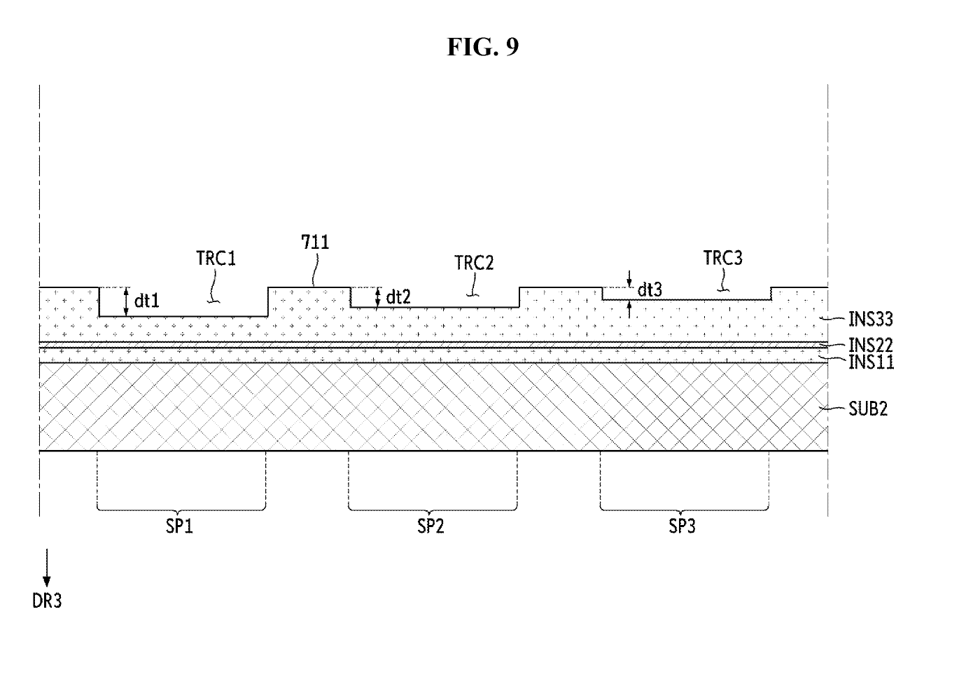

Next, as illustrated in FIG. 9, the third insulating layer INS33 of the third sub-pixel area SP3 may be removed by patterning the third insulating layer INS33 (e.g., the third insulating layer INS33 including the first trench TRC1 and the second trench TRC2) through a photolithography process. Accordingly, a third trench TRC3 overlapping the third sub-pixel area SP3 may be formed.

The first trench TRC1, the second trench TRC2, and the third trench TRC3 may have different depths. For example, a depth dt2 of the second trench TRC2 may be greater than a depth dt3 of the third trench TRC3 and smaller than a depth dt1 of the first trench TRC1. Here, the depth may be a distance from an upper surface 711 of the third insulating layer INS33 to a bottom surface of the corresponding trench in a third reverse direction. Accordingly, in the third direction DR3, the bottom surface of the second trench TRC2 may be higher than the bottom surface of the first trench TRC1 and lower than the bottom surface of the third trench TRC3.

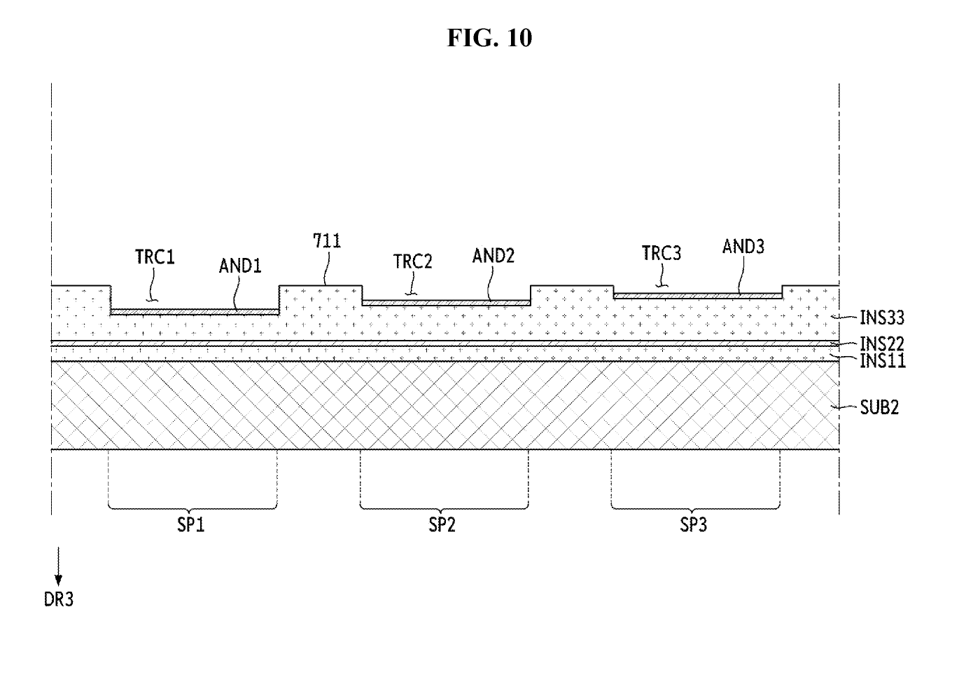

Next, as illustrated in FIG. 10, a first anode electrode AND1 may be formed in the first trench TRC1, a second anode electrode AND2 may be formed in the second trench TRC2, and a third anode electrode AND3 may be formed in the third trench TRC3 through a photolithography process. As the bottom surface of the first trench TRC1, the bottom surface of the second trench TRC2, and the bottom surface of the third trench TRC3 are disposed at different heights, the first anode electrode AND1, the second anode electrode AND2, and the third anode electrode AND3 may be disposed at different heights. For example, in the third direction DR3, the second anode electrode AND2 may be higher than the first anode electrode AND1 and lower than the third anode electrode AND3. Next, an annealing process may be performed on the second substrate SUB2 including the first anode electrode AND1, the second anode electrode AND2, and the third anode electrode AND3. Hydrogen fluoride (e.g., Diluted HF) may be used during the patterning process or cleaning process (or both) of the first anode electrode AND1, the second anode electrode AND2, and the third anode electrode AND3.

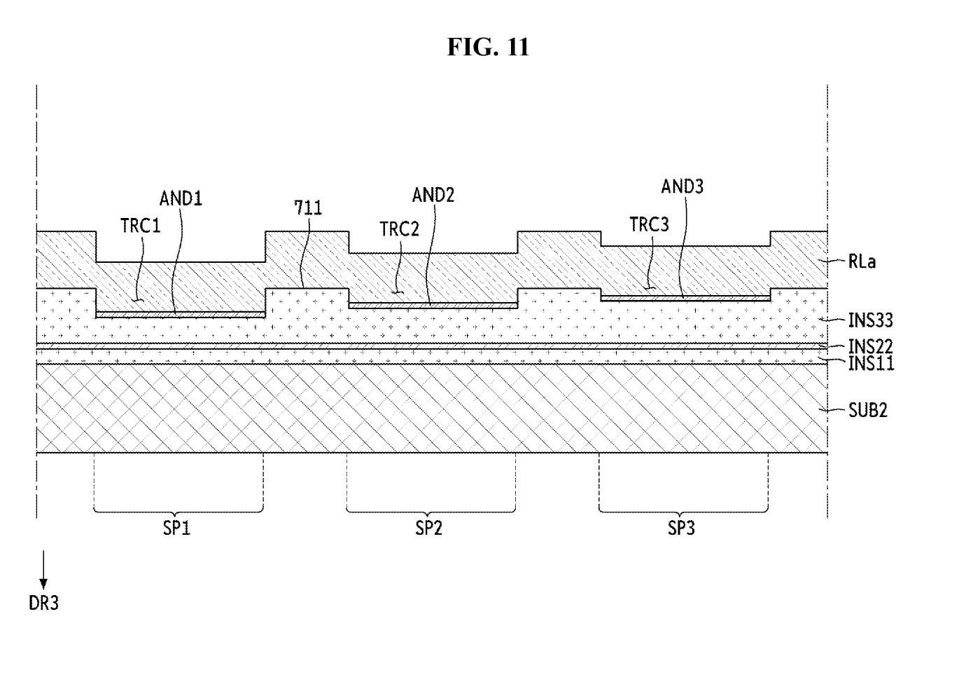

Next, as illustrated in FIG. 11, a preliminary reflective electrode RLa may be formed on the first anode electrode AND1, the second anode electrode AND2, the third anode electrode AND3, and the third insulating layer INS33, and the preliminary reflective electrode RLa may be formed within the first to third trenches TRC1, TRC2, and TRC3. For example, the preliminary reflective electrode RLa may be formed on an entire surface of the second substrate SUB2 including the first anode electrode AND1, the second anode electrode AND2, the third anode electrode AND3, the third insulating layer INS33, the first trench TRC1, the second trench TRC2, and the third trench TRC3.

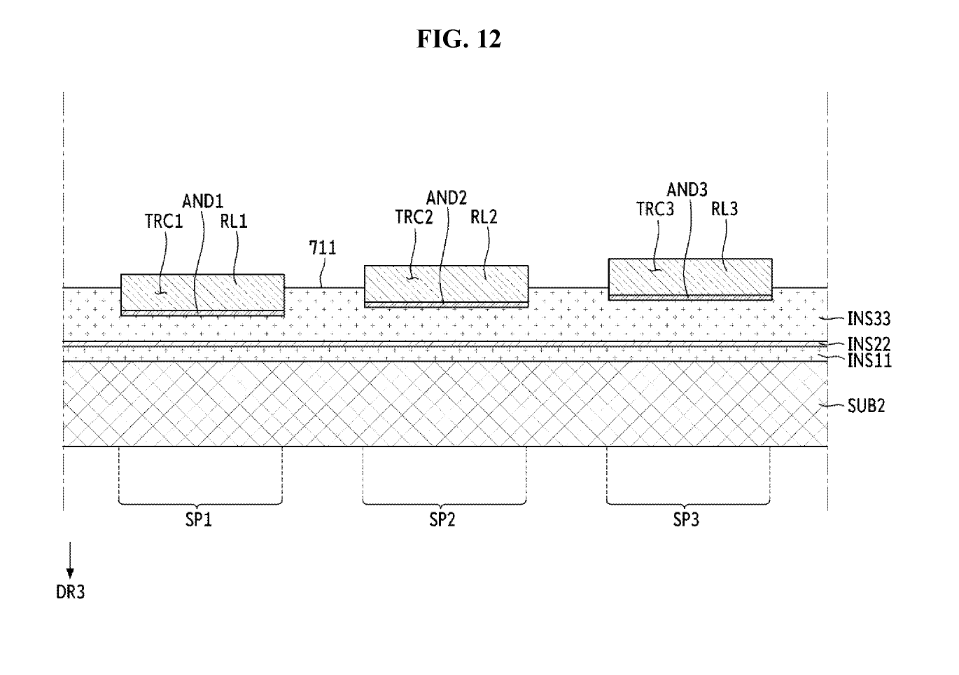

Next, as illustrated in FIG. 12, the preliminary reflective electrode RLa outside the first trench TRC1, the second trench TRC2, and the third trench TRC3 may be removed by patterning the preliminary reflective electrode RLa through a photolithography process. Accordingly, a first reflective electrode RL1 in contact with the first anode electrode AND1 may be formed on the first anode electrode AND1, a second reflective electrode RL2 in contact with the second anode electrode AND2 may be formed on the second anode electrode AND2, and a third reflective electrode RL3 in contact with the third anode electrode AND3 may be formed on the third anode electrode AND3. In this case, a portion of the first reflective electrode RL1 may be disposed within the first trench TRC1, a portion of the second reflective electrode RL2 may be disposed within the second trench TRC2, and a portion of the third reflective electrode RL3 may be disposed within the third trench TRC3.

According to an embodiment, since the first to third anode electrodes AND1, AND2, and AND3 are formed before the first to third reflective electrodes RL1, RL2, and RL3, hydrogen fluoride used when cleaning (or patterning) the first to third anode electrodes AND1, AND2, and AND3 made of an ITO material may not affect the first to third reflective electrodes RL1, RL2, and RL3. Therefore, the problem of the reflective electrode being damaged by hydrogen fluoride during the process of cleaning (or patterning) the anode electrode in the state in which the reflective electrode is first formed may be solved. Here, the problem of forming the anode electrode after the reflective electrode is formed is described as follows.

For example, when the anode electrode is made of a material including ITO, the anode electrode may have a plurality of pin holes. Therefore, an aluminum component of the reflective electrode RL may protrude onto the anode electrode through the pin holes of the anode electrode. In other words, since a portion of the reflective electrode may swell due to heat during a curing process (e.g., heat treatment process) to alleviate defects that may occur in the subsequent process, the swollen portion of the reflective electrode may be exposed to the outside through the pin holes of the anode electrode. In this case, a portion of the reflective electrode exposed to the outside through the pin holes may be exposed to hydrogen fluoride used in the above-described cleaning process. Then, hydrogen fluoride may permeate into the reflective electrode through the exposed portion of the reflective electrode as a permeation path. In such a case, the reflective electrode may be damaged. When the reflective electrode is damaged by exposure to hydrogen fluoride, at least a portion of the reflective electrode may melt and be lost. In such a case, a light efficiency in the light emitting area where the reflective electrode is lost may decrease, which may deteriorate an image quality of the display device 10.

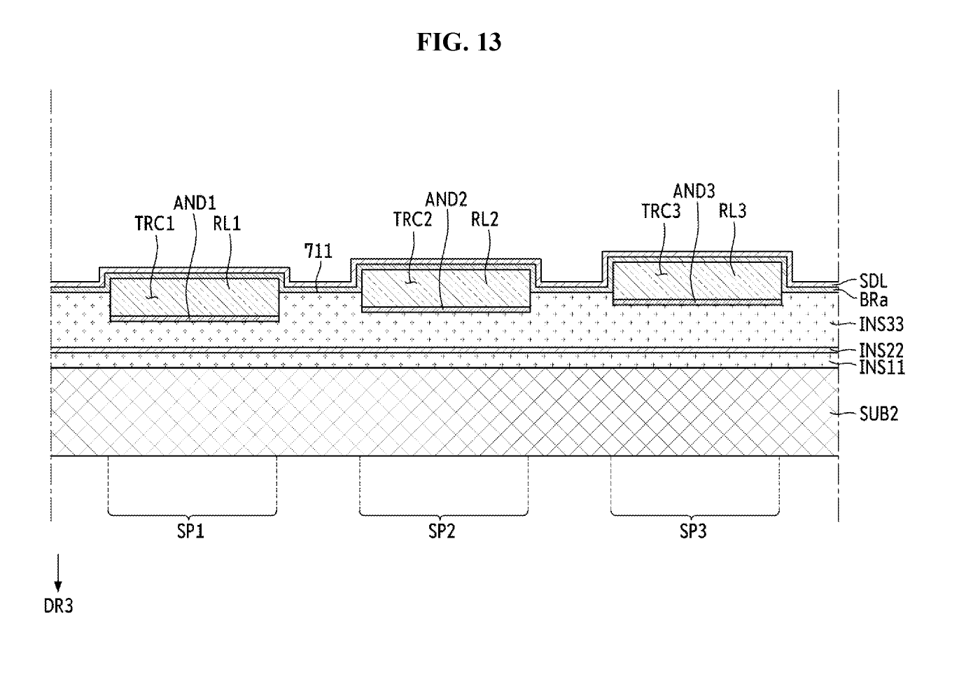

Next, as illustrated in FIG. 13, a preliminary diffusion barrier layer BRa may be formed on the first reflective electrode RL1, the second reflective electrode RL2, the third reflective electrode RL3, and the third insulating layer INS33. For example, the preliminary diffusion barrier layer BRa may be formed on the entire surface of the second substrate SUB2 including the first reflective electrode RL1, the second reflective electrode RL2, the third reflective electrode RL3, and the third insulating layer INS33. The preliminary diffusion barrier layer BRa may be made of a material including any one of titanium, titanium nitride, tantalum, and tantalum nitride. The preliminary diffusion barrier layer BRa may be a barrier layer that prevents a diffusion of copper when forming a pad using a seed layer SDL including copper, which will be described later.

Next, a seed layer SDL may be formed on the preliminary diffusion barrier layer BRa. For example, the seed layer SDL may be formed on the entire surface of the second substrate SUB2 including the preliminary diffusion barrier layer BRa. The seed layer SDL may be made of a material including one of copper and a Cu-Mn alloy.

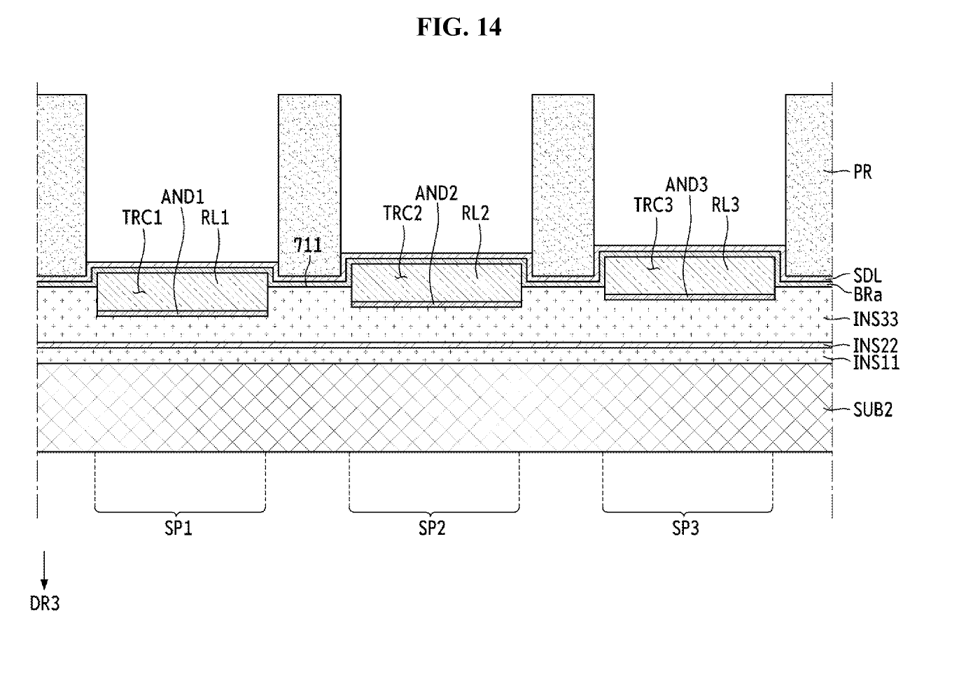

Thereafter, as illustrated in FIG. 14, a photoresist pattern PR may be formed on the seed layer SDL so as not to overlap the first reflective electrode RL1, the second reflective electrode RL2, and the third reflective electrode RL3. For example, the photoresist pattern PR may be disposed on the seed layer SDL so as to overlap an interface between the third insulating layer INS33 and the preliminary diffusion barrier layer BRa.

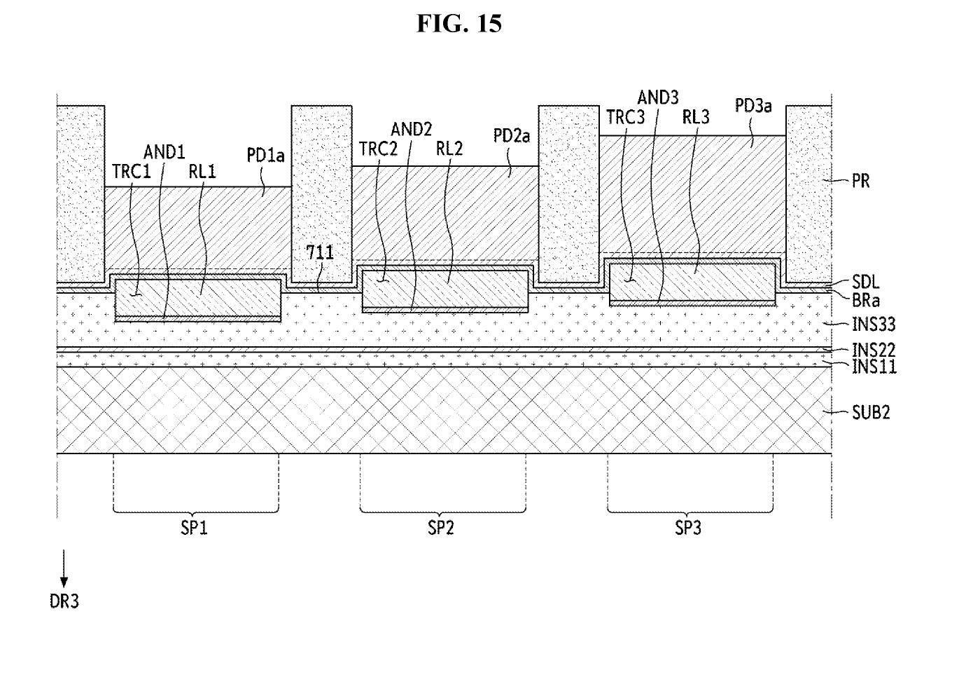

Next, as illustrated in FIG. 15, a first preliminary pad PD1a in contact with the first reflective electrode RL1 may be formed on the first reflective electrode RL1, a second preliminary pad PD2a in contact with the second reflective electrode RL2 may be formed on the second reflective electrode RL2, and a third preliminary pad PD3a in contact with the third reflective electrode RL3 may be formed on the third reflective electrode RL3, by selectively growing the seed layer SDL of the first sub-pixel area SP1, the seed layer SDL of the second sub-pixel area SP2, and the seed layer SDL of the third sub-pixel area SP3 using the photoresist pattern PR as a mask. Here, the seed layer SDL of the first sub-pixel area SP1, the seed layer SDL of the second sub-pixel area SP2, and the seed layer SDL of the third sub-pixel area SP3 may be grown, for example, by an electroplating method. Here, a thickness of the first preliminary pad PD1a, a thickness of the second preliminary pad PD2a, and a thickness of the third preliminary pad PD3a may be the same or different.

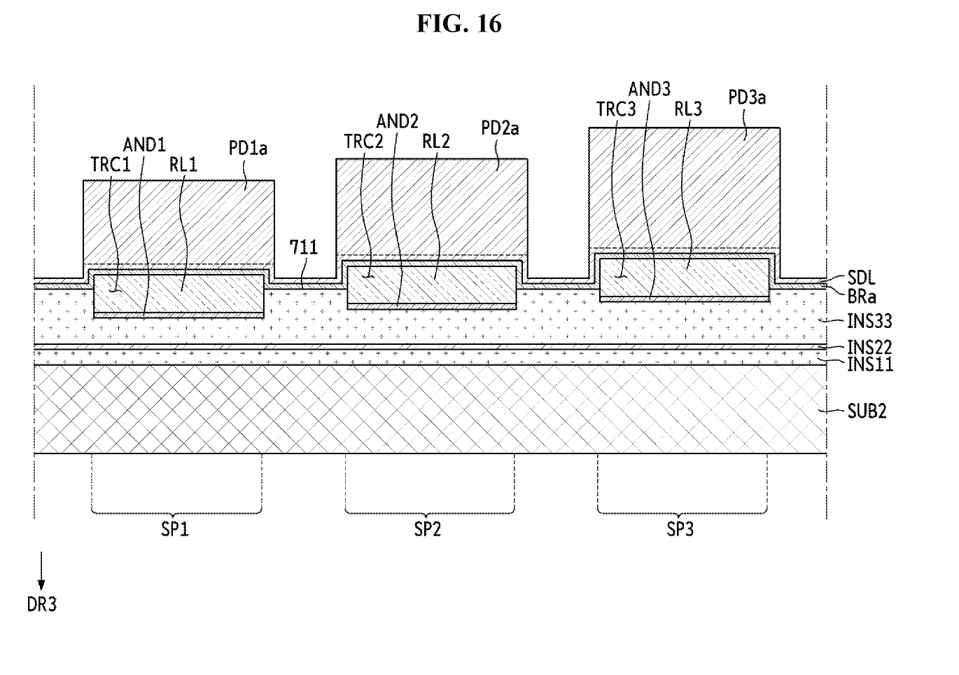

Thereafter, the photoresist pattern PR may be removed, as illustrated in FIG. 16. For example, the photoresist pattern PR may be removed by a stripper. As the photoresist pattern PR is removed, the preliminary diffusion barrier layer BRa and the seed layer SDL between adjacent reflective electrodes RL1, RL2, and RL3 may be exposed.

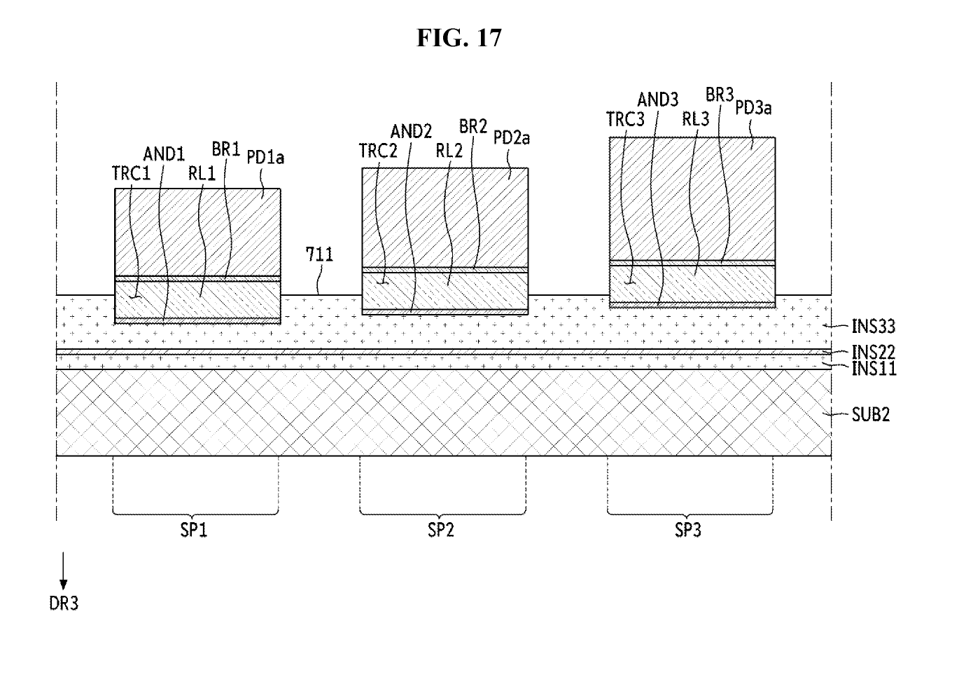

Next, as illustrated in FIG. 17, the preliminary diffusion barrier layer BRa and the seed layer SDL between the reflective electrodes RL1, RL2, and RL3 may be removed by patterning the preliminary diffusion barrier layer BRa and the seed layer SDL through a photolithography process. Accordingly, a first diffusion barrier layer BR1 may be formed between the first reflective electrode RL1 and the first preliminary pad PD1a, a second diffusion barrier layer BR2 may be formed between the second reflective electrode RL2 and the second preliminary pad PD2a, and a third diffusion barrier layer BR3 may be formed between the third reflective electrode RL3 and the third preliminary pad PD3a. In addition, the upper surface 711 of the third insulating layer INS33 between the reflective electrodes RL1, RL2, and RL3 may be exposed.

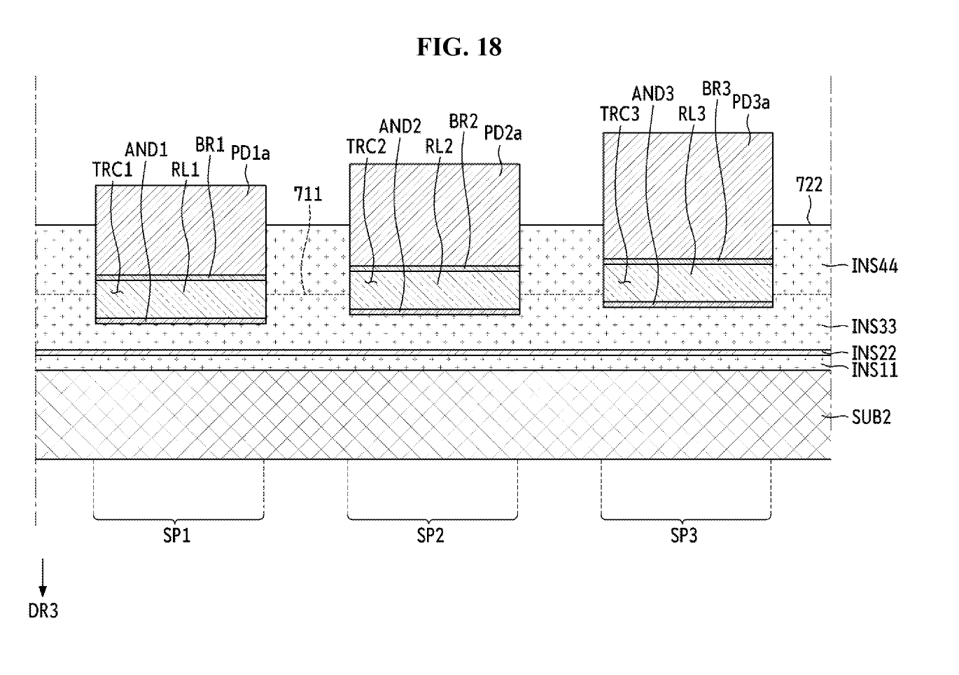

Thereafter, as illustrated in FIG. 18, a fourth insulating layer INS44 may be formed on the third insulating layer INS33. In this case, an upper surface 722 of the fourth insulating layer INS44 may be lower than an upper surface of the first preliminary pad PD1a, which is disposed to be lowest among the first to third preliminary pads PD1a, PD2a, and PD3a. Accordingly, the first to third preliminary pads PD1a, PD2a, and PD3a may protrude to the outside through the upper surface 722 of the fourth insulating layer INS44 in the third reverse direction. The fourth insulating layer INS44 may be made of the same material as the third insulating layer INS33. For example, the fourth insulating layer INS44 may be made of a material including silicon oxide (SiO₂). Accordingly, the fourth insulating layer INS44 and the third insulating layer INS33 may be formed integrally without an interface.

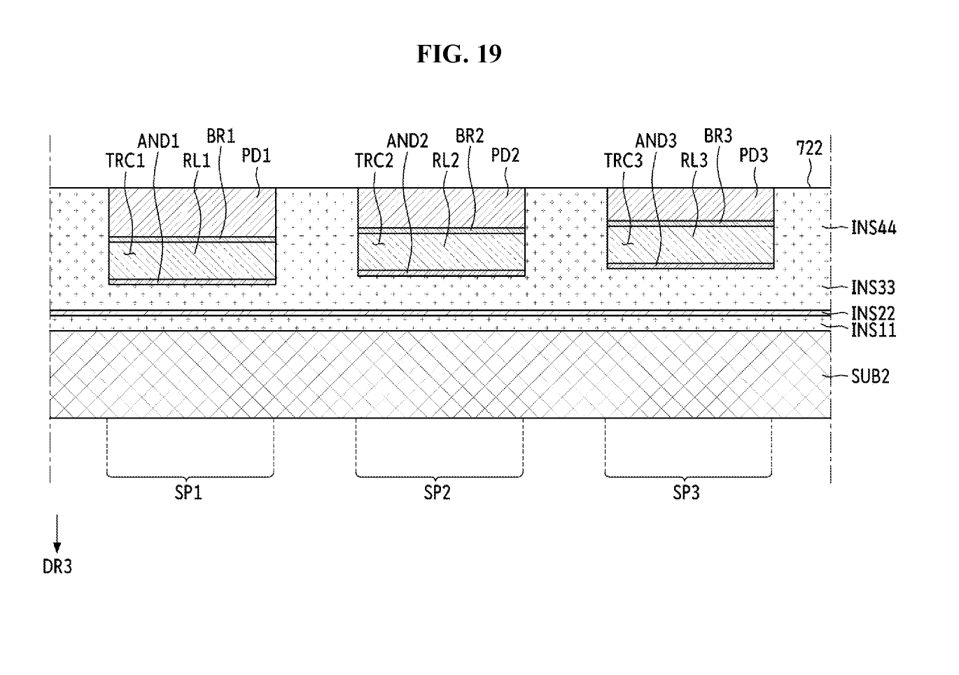

Next, as illustrated in FIG. 19, the first preliminary pad PD1a, the second preliminary pad PD2a, and the third preliminary pad PD3a may be removed to the upper surface 722 of the fourth insulating layer INS44. For example, by removing the first preliminary pad PD1a, the second preliminary pad PD2a, and the third preliminary pad PD3a that protrude higher in the third reverse direction than the upper surface of the fourth insulating layer INS44 by a chemical mechanical polishing (CMP) method, a first pad PD1, a second pad PD2, and a third pad PD3 may be formed. In other words, as the first preliminary pad PD1a, the second preliminary pad PD2a, and the third preliminary pad PD3a that protrude at different heights are removed to the upper surface of the fourth insulating layer INS44, the upper surface of each of the first preliminary pad PD1a, the second preliminary pad PD2a, and the third preliminary pad PD3a may be planarized. Accordingly, an upper surface of each of the first pad PD1, the second pad PD2, and the third pad PD3 may be disposed at substantially the same height as the upper surface 722 of the fourth insulating layer INS44. In other words, the upper surface of the first pad PD1, the upper surface of the second pad PD2, and the upper surface of the third pad PD3 may substantially coincide with the upper surface 722 of the fourth insulating layer INS44. Accordingly, the first pad PD1, the second pad PD2, and the third pad PD3 may have different thicknesses in the third direction DR3 with respect to the upper surface 722 of the fourth insulating layer INS44.

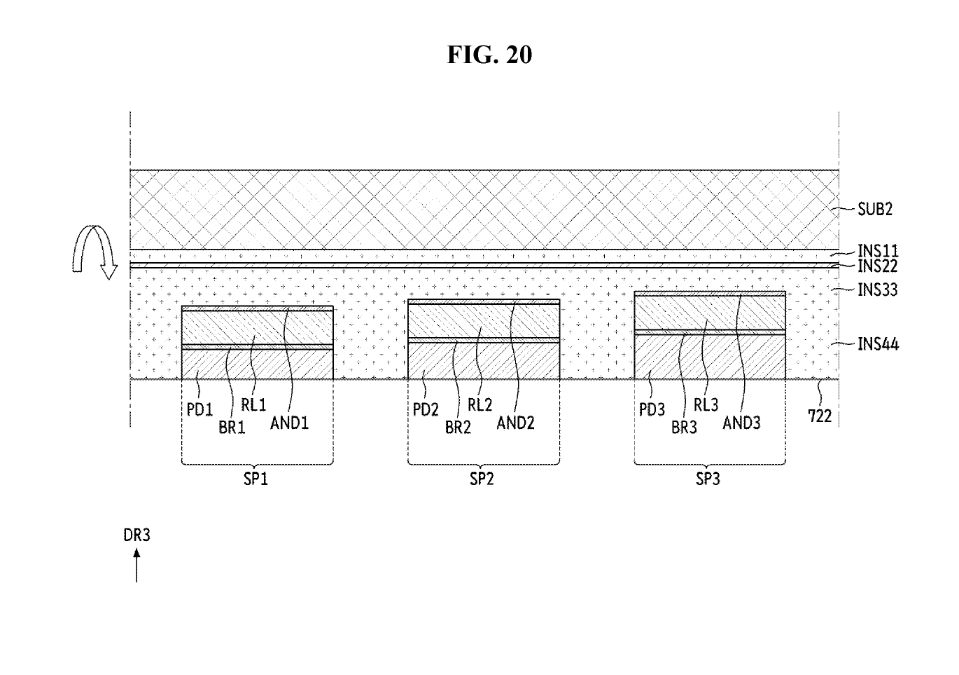

Thereafter, as illustrated in FIG. 20, the second substrate SUB2 and structures on the second substrate SUB2 may be rotated by 180 degrees so that the second substrate SUB2 faces upward.

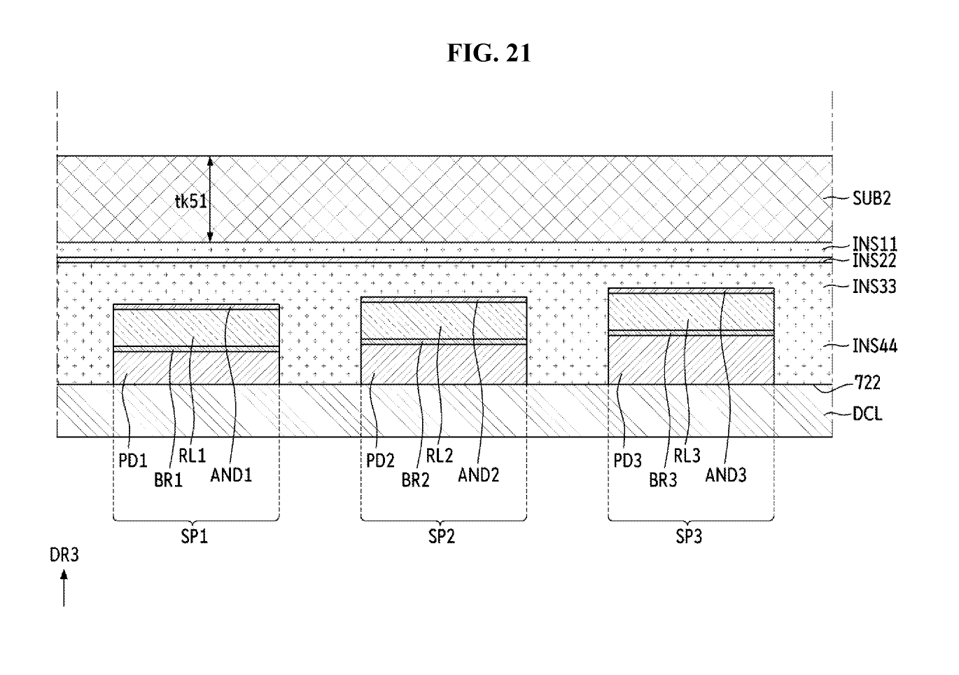

Next, as illustrated in FIG. 21, a driving circuit layer DCL may be formed on the upper surface 722 of the fourth insulating layer INS44. For example, a first substrate SUB1 having first to third transistors TR1, TR2, and TR3 and first to third bumps BP1, BP2, and BP3 disposed thereon may be attached to the first to third pads PD1, PD2, and PD3 and the fourth insulating layer INS44 of the second substrate SUB2. In this case, the first bump BP1, the second bump BP2, and the third bump BP3 of the driving circuit layer DCL may be in contact with the first pad PD1, the second pad PD2, and the third pad PD3 on the second substrate SUB2, respectively. Accordingly, the first bump BP1, the second bump BP2, and the third bump BP3 may be connected to the first pad PD1, the second pad PD2, and the third pad PD3 on the second substrate SUB2, respectively.

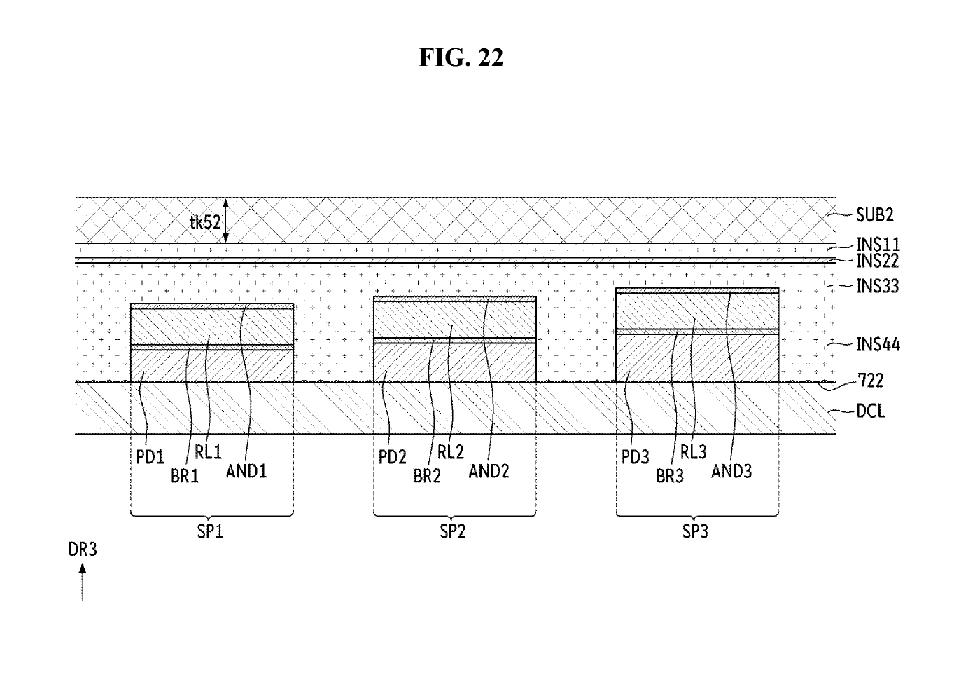

Thereafter, as illustrated in FIG. 22, a lower surface of the second substrate SUB2 may be removed. For example, the second substrate SUB2 may be removed from the lower surface of the second substrate SUB2 along the third reverse direction by a grinding method. Accordingly, a thickness of the second substrate SUB2 may be reduced. For example, a thickness tk52 of the second substrate SUB2 of FIG. 22 may be smaller than a thickness tk51 of the second substrate SUB2 of FIG. 21.

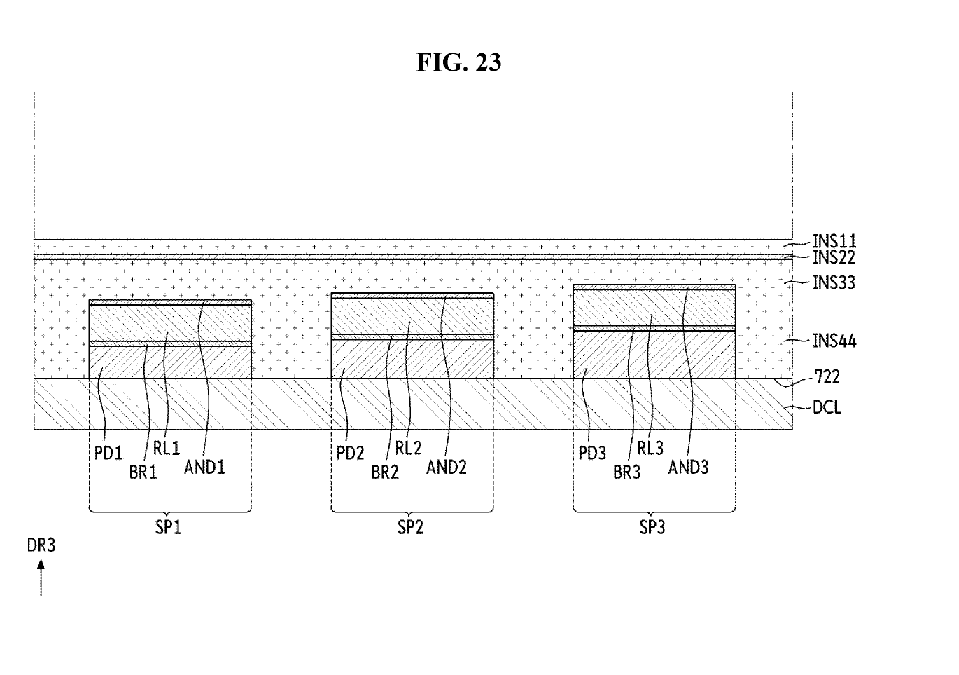

Next, as illustrated in FIG. 23, the remaining portion of the second substrate SUB2 may be removed by an etching method. In this way, as the second substrate SUB2 is completely removed, the first insulating layer INS11 may be exposed.

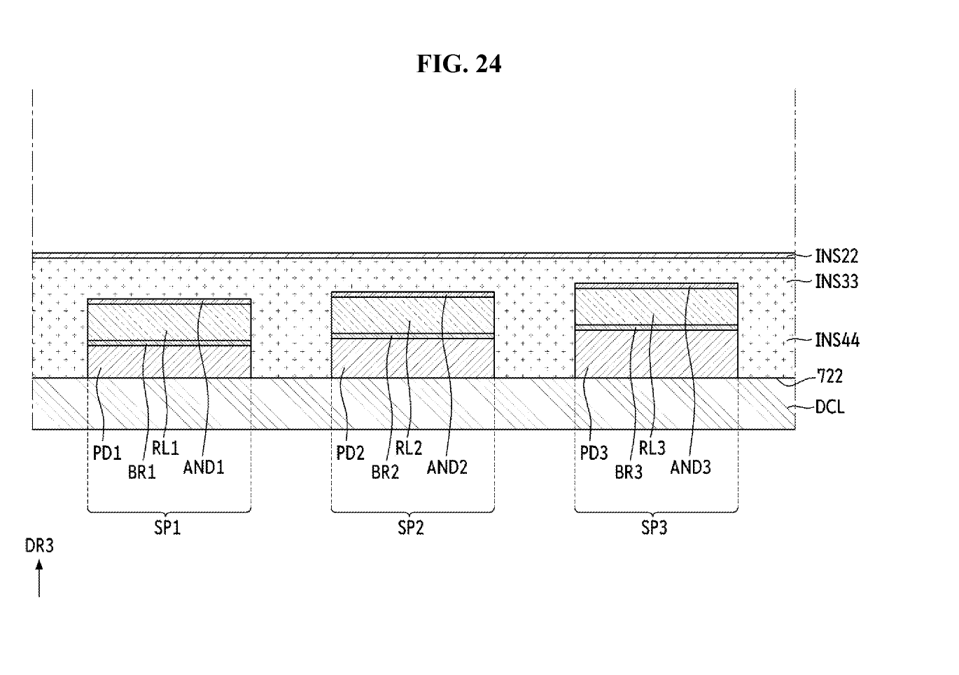

Thereafter, as illustrated in FIG. 24, the first insulating layer INS11 may be removed. For example, the first insulating layer INS11 may be removed by an etching method. Accordingly, the second insulating layer INS22 may be exposed.

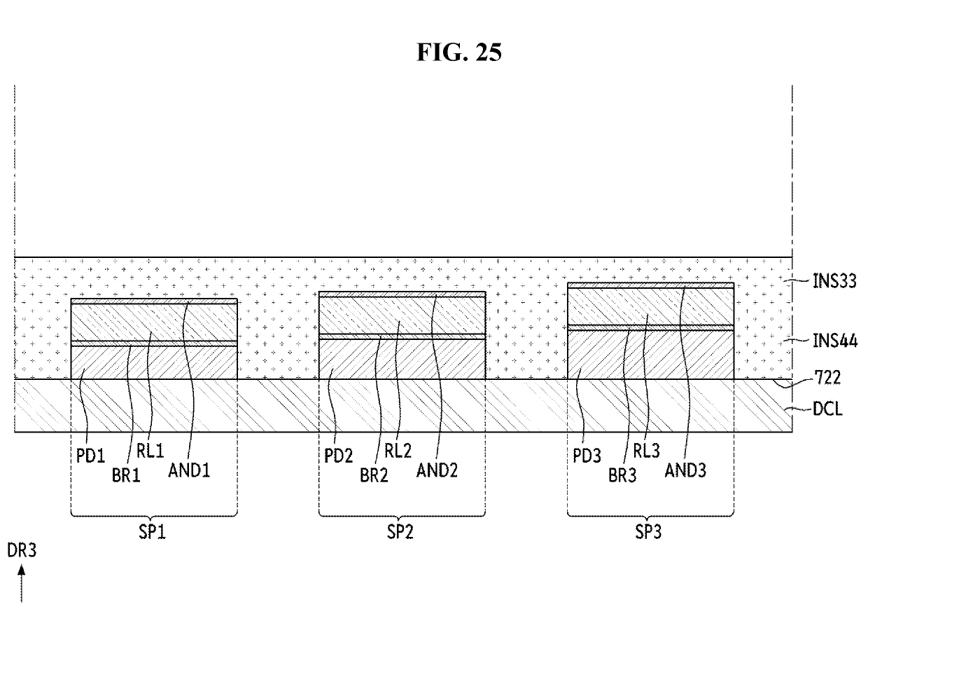

Next, as illustrated in FIG. 25, the second insulating layer INS22 may be removed. For example, the second insulating layer INS22 may be removed by an etching method. Accordingly, the third insulating layer INS33 may be exposed.

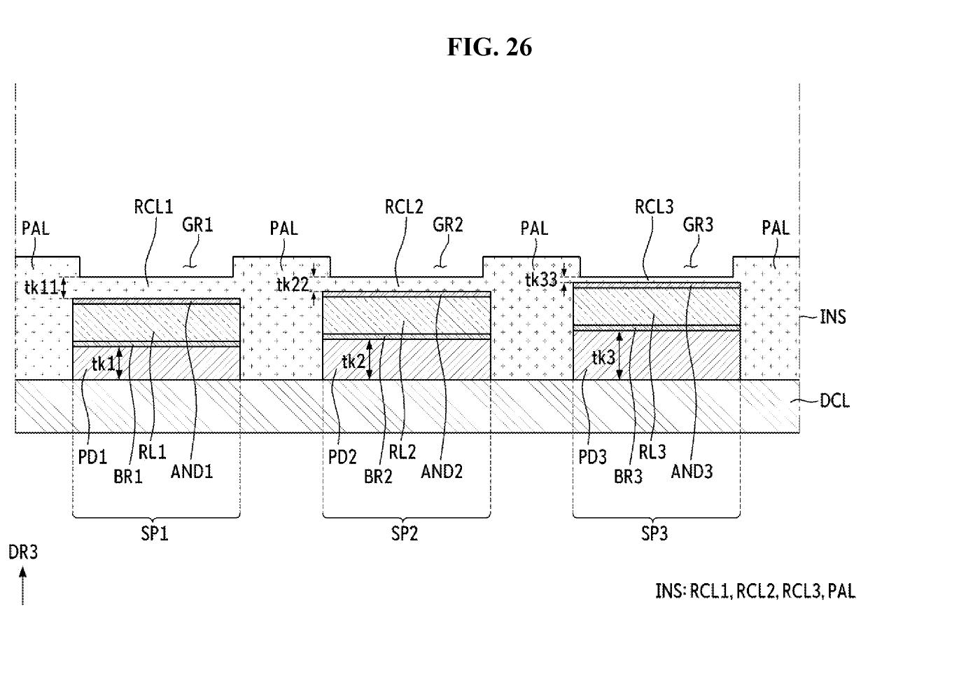

Next, as illustrated in FIG. 26, by patterning the third insulating layer INS33 through a photolithography process, an insulating layer INS including a first groove GR1 overlapping the first anode electrode AND1, a second groove GR2 overlapping the second anode electrode AND2, a third groove GR3 overlapping the third anode electrode AND3, a first resonance control layer RCL1 disposed between the first anode electrode AND1 and the first groove GR1, a second resonance control layer RCL2 disposed between the second anode electrode AND2 and the second groove GR2, and a third resonance control layer RCL3 disposed between the third anode electrode AND3 and the third groove GR3, and a partition layer PAL disposed between the sub-pixel areas SP1, SP2, and SP3 may be formed. Here, the first resonance control layer RCL1, the second resonance control layer RCL2, and the third resonance control layer RCL3 may have different thicknesses (tk11>tk22<tk33).

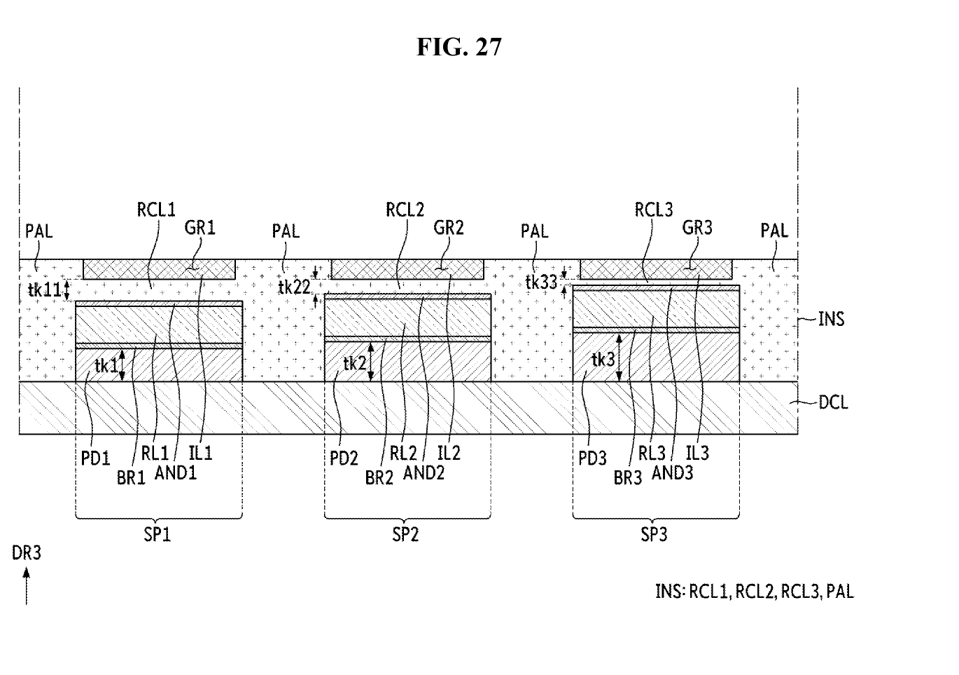

Next, as illustrated in FIG. 27, a first light emitting stack layer IL1 may be formed in the first groove GR1, a second light emitting stack layer IL2 may be formed in the second groove GR2, and a third light emitting stack layer IL3 may be formed in the third groove GR3. In this case, the first light emitting stack layer IL1, the second light emitting stack layer IL2, and the third light emitting stack layer IL3 may be simultaneously formed.

Thereafter, as illustrated in FIG. 4, a cathode electrode CAT may be disposed on the first light emitting stack layer IL1, the second light emitting stack layer IL2, the third light emitting stack layer IL3, and the insulating layer INS. Thereafter, an encapsulation layer ENC may be formed on the cathode electrode CAT. Thereafter, a first color filter CF1, a second color filter CF2, and a third color filter CF3 may be formed on the encapsulation layer ENC. In this case, the first color filter CF1 may be disposed on the encapsulation layer ENC to overlap the first light emitting stack layer IL1, the second color filter CF2 may be disposed on the encapsulation layer ENC to overlap the second light emitting stack layer IL2, and the third color filter CF3 may be disposed on the encapsulation layer ENC to overlap the third light emitting stack layer IL3. Thereafter, a first lens LNS1 may be formed on the first color filter CF1, a second lens LNS2 may be formed on the second color filter CF2, and a third lens LNS3 may be formed on the third color filter CF3. In this case, the first lens LNS1, the second lens LNS2, and the third lens LNS3 may be simultaneously formed.

The display device 10 according to the embodiment may be applied to various electronic devices. An electronic device according to an embodiment may include the display device 10 described above, and may further include a module or device having additional functions in addition to the display device 10.

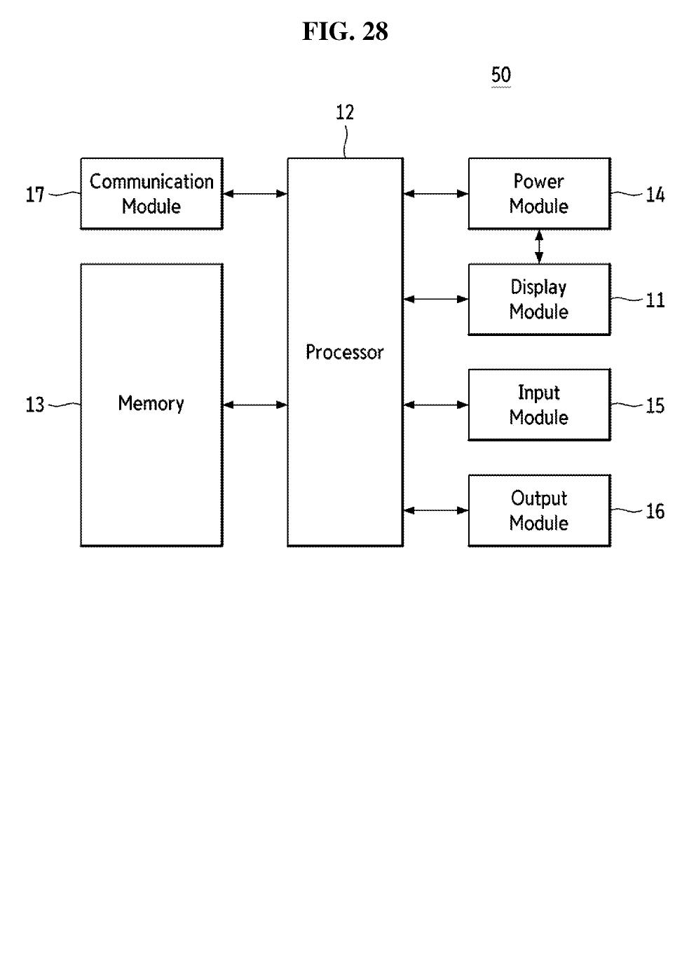

FIG. 28 is a block diagram of an electronic device according to an embodiment. Referring to FIG. 28, an electronic device 50 according to an embodiment may include a display module 11, a processor 12, a memory 13, and a power module 14. The electronic device 50 may further include an input module 15, a non-image output module 16, and a communication module 17.

The electronic device 50 may output various information in the form of an image through the display module 11. When the processor 12 executes an application stored in the memory 13, image information provided by the application may be provided to the user through the display module 11. The power module 14 may include a power supply module, such as a power adapter or a battery device, and a power conversion module that converts power supplied by the power supply module to generate power required for an operation of the electronic device 50. The input module 15 may provide input information to the processor 12 and the display module 11. The non-image output module 16 may serve to receive information other than the image received from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 50 other than the display device.

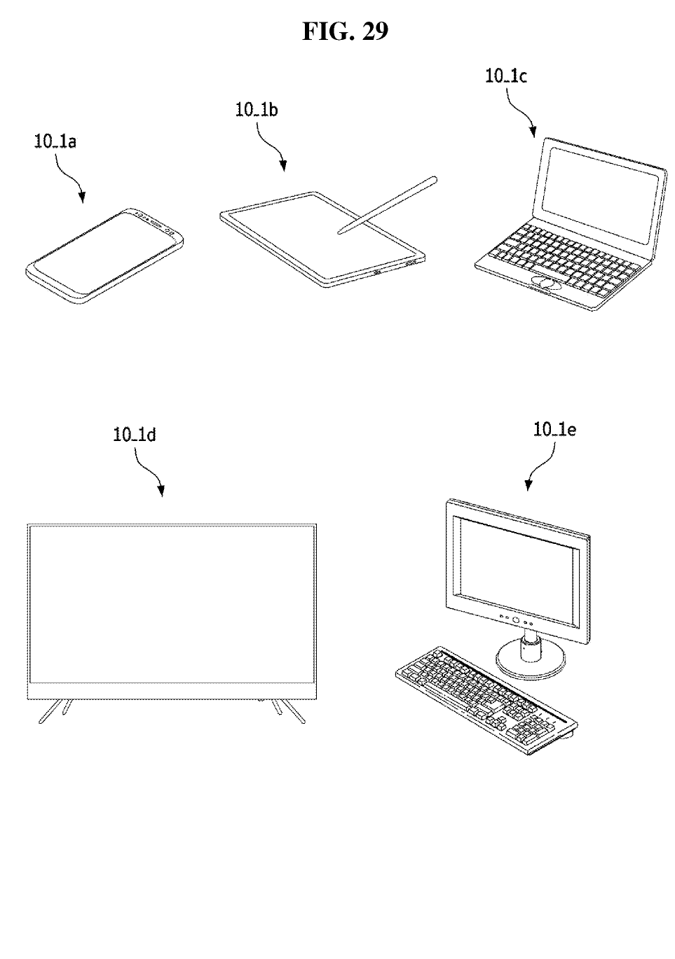

FIGS. 29, 30, and 31 are schematic diagrams of electronic devices according to various embodiments. FIGS. 29-31 illustrate examples of various electronic devices to which the display device 10 according to the embodiments is applied.

FIG. 29 illustrates examples of the electronic devices, including a smartphone 10_1a, a tablet PC 10_1b, a laptop 10_1c, a TV 10_1d, and a desk monitor 10_1e.

The smartphone 10_1a may include an input module such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e also include a display module and an input module similarly to the smartphone 10_1a, and in some cases, may further include a communication module.

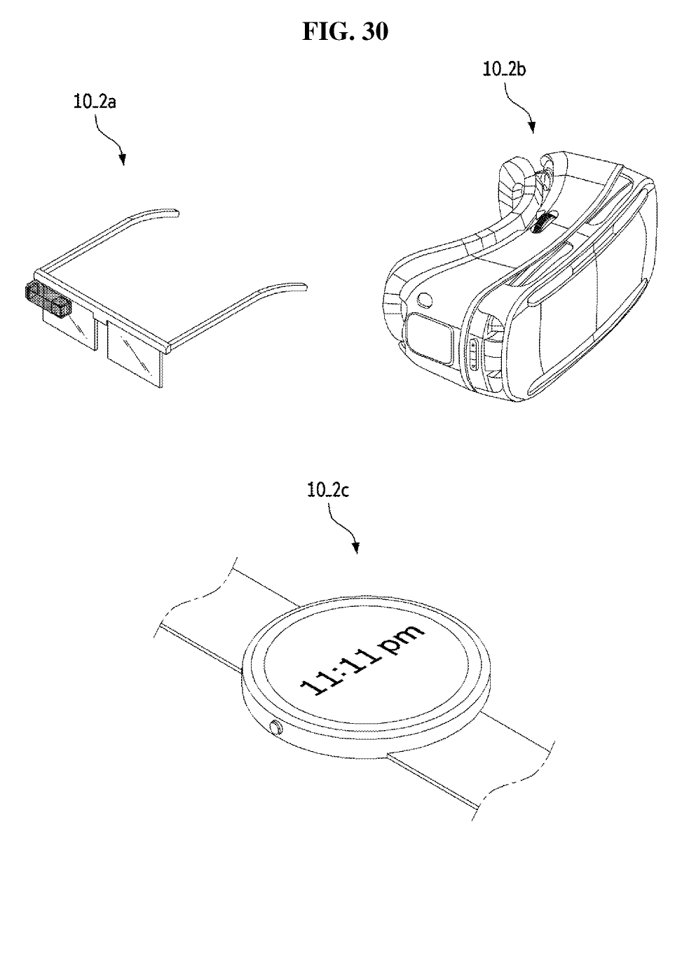

FIG. 30 illustrates a case in which an electronic device including a display module is applied to a wearable electronic device. The wearable electronic device may be a smart glasses 10_2a, a head mounted display 10_2b, a smart watch 10_2c, etc.

The smart glasses 10_2a and the head mounted display 10_2b may include a display module that emits a display image and a reflector that reflects the emitted display image and provides the reflected display image to the user's eyes, and may provide the user with a virtual reality or augmented reality screen through the display module and the reflector.

The smart watch 10_2c includes a biometric sensor as an input device and may provide the biometric information recognized by the biometric sensor to the user through the display module.

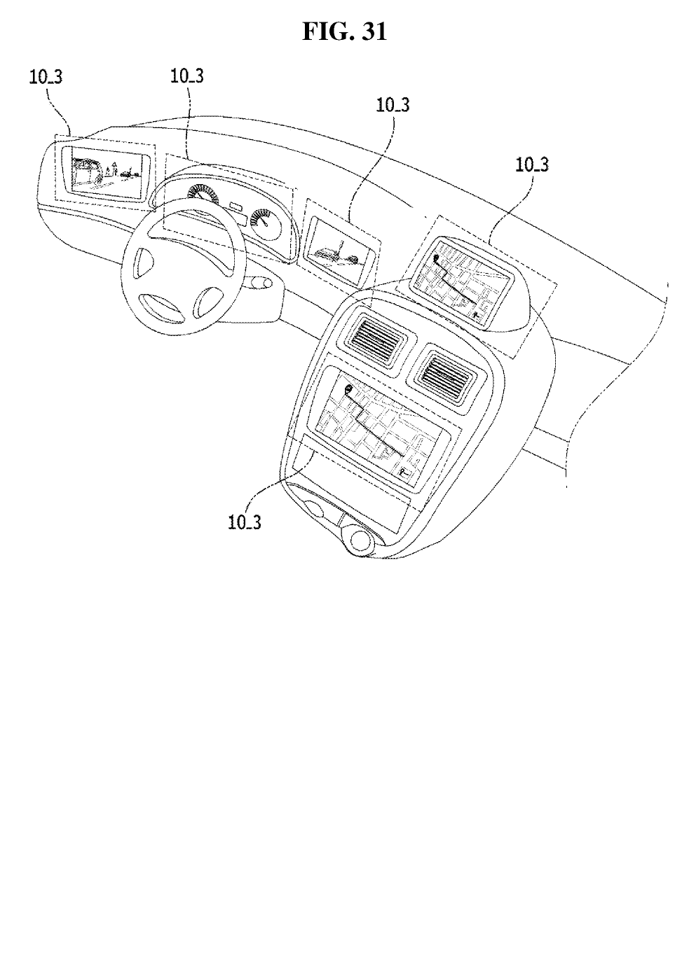

FIG. 31 illustrates an example in which an electronic device including a display module is applied to a vehicle. For example, an electronic device 10_3 may be applied to a dashboard, center fascia, etc. of an automobile, or may be applied to a Center Information Display (CID) disposed on the dashboard of the automobile or a room mirror display replacing a side mirror.

In concluding the detailed description, those skilled in the art will appreciate that many variations and modifications can be made to the preferred embodiments without substantially departing from the principles of the present inventive concept. Therefore, the disclosed preferred embodiments of the inventive concept are used in a generic and descriptive sense only and not for purposes of limitation.

What is claimed is:

1. A display device comprising:
a substrate including a first sub-pixel area;
a first pad disposed on the substrate so as to overlap the first sub-pixel area;
a first reflective electrode disposed on the first pad;
a first anode electrode disposed on the first reflective electrode;
a first resonance control layer disposed on the first anode electrode;
a first light emitting stack layer disposed on the first resonance control layer; and
a cathode electrode disposed on the first light emitting stack layer.

2. The display device of claim 1, further comprising an insulating layer including the first resonance control layer,
wherein the insulating layer includes a first groove disposed on the first resonance control layer so as to overlap the first resonance control layer, and
the first anode electrode is disposed within the first groove of the insulating layer.

3. The display device of claim 2, wherein the substrate further includes a second sub-pixel area adjacent to the first sub-pixel area.

4. The display device of claim 3, further comprising:
a second pad disposed on the substrate so as to overlap the second sub-pixel area;
a second reflective electrode disposed on the second pad;
a second anode electrode disposed on the second reflective electrode;
a second resonance control layer disposed on the second anode electrode; and
a second light emitting stack layer disposed on the second resonance control layer,
wherein the cathode electrode is disposed on the first light emitting stack layer, the second light emitting stack layer, and the insulating layer.

5. The display device of claim 4, wherein a thickness of the second pad is greater than a thickness of the first pad.

6. The display device of claim 4, wherein a thickness of the second reflective electrode and a thickness of the first reflective electrode is a same thickness.

7. The display device of claim 6, wherein the second reflective electrode is higher than the first reflective electrode relative to the substrate.

8. The display device of claim 4, wherein the second anode electrode is higher than the first anode electrode relative to the substrate.

9. The display device of claim 4, wherein a thickness of the second resonance control layer is smaller than a thickness of the first resonance control layer.

10. The display device of claim 4, wherein the insulating layer further includes:
a second groove disposed on the second resonance control layer so as to overlap the second resonance control layer, and
the second anode electrode is disposed within the second groove of the insulating layer.

11. The display device of claim 4, further comprising:
a first diffusion barrier layer disposed between the first pad and the first reflective electrode; and
a second diffusion barrier layer disposed between the second pad and the second reflective electrode.

12. The display device of claim 11, wherein the second diffusion barrier layer is higher than the first diffusion barrier layer relative to the substrate.

13. The display device of claim 4, wherein the insulating layer further includes a partition layer disposed between the first sub-pixel area and the second sub-pixel area.

14. The display device of claim 13, wherein the partition layer is disposed:
between the first pad and the second pad,
between the first reflective electrode and the second reflective electrode,
between the first anode electrode and the second anode electrode,
between the first resonance control layer and the second resonance control layer, and
between the first light emitting stack layer and the second light emitting stack layer.

15. The display device of claim 1, further comprising a transistor disposed between the substrate and the first pad and connected to the first pad.

16. The display device of claim 15, further comprising a bump disposed between the first pad and the transistor and connected to the first pad and the transistor.

17. An electronic device comprising:
a display device including a display screen,
wherein the display device includes:
a substrate including a first sub-pixel area;
a first pad disposed on the substrate so as to overlap the first sub-pixel area;
a first reflective electrode disposed on the first pad;
a first anode electrode disposed on the first reflective electrode;
a first resonance control layer disposed on the first anode electrode;
a first light emitting stack layer disposed on the first resonance control layer; and
a cathode electrode on the first light emitting stack layer.

18. The electronic device of claim 17, wherein the display device further includes an insulating layer including the first resonance control layer,
the insulating layer includes a first groove disposed on the first resonance control layer so as to overlap the first resonance control layer, and
the first anode electrode is disposed within the first groove of the insulating layer.

19. The electronic device of claim 17, wherein the electronic device is a wearable device including a head mounted display, smart glasses, or a smart watch.

20. A method for fabricating a display device, the method comprising:
preparing a first substrate having a first sub-pixel area and a second sub-pixel area;
forming a first insulating layer on the first substrate, forming a second insulating layer on the first insulating layer, and forming a third insulating layer on the second insulating layer;
forming a first trench and a second trench having different depths in the first sub-pixel area and the second sub-pixel area, respectively, in the third insulating layer;
forming a first anode electrode in the first trench and forming a second anode electrode in the second trench;
forming a preliminary reflective electrode on the first anode electrode, the second anode electrode, and the third insulating layer;
forming a first reflective electrode in contact with the first anode electrode and a second reflective electrode in contact with the second anode electrode by patterning the preliminary reflective electrode;
forming a preliminary diffusion barrier layer on the first reflective electrode, the second reflective electrode, and the third insulating layer;
forming a seed layer on the preliminary diffusion barrier layer;
forming a photoresist pattern on the seed layer so as not to overlap the first reflective electrode and the second reflective electrode;
forming a first preliminary pad in contact with the first reflective electrode and a second preliminary pad in contact with the second reflective electrode by growing the seed layer using the photoresist pattern as a mask:
removing the photoresist pattern;
exposing the third insulating layer by removing the preliminary diffusion barrier layer and the seed layer between the first reflective electrode and the second reflective electrode;
forming a fourth insulating layer on the third insulating layer;
forming a first pad and a second pad having different thicknesses relative to an upper surface of the fourth insulating layer by planarizing the first preliminary pad and the second preliminary pad, respectively;
rotating the first substrate by 180 degrees;
bringing a first bump and a second bump of a second substrate into contact with the first pad and the second pad, respectively, by attaching the second substrate onto the fourth insulating layer;
exposing the third insulating layer by removing the first substrate, the first insulating layer, and the second insulating layer;
forming an insulating layer including a first groove overlapping the first anode electrode, a second groove overlapping the second anode electrode, a first resonance control layer disposed between the first anode electrode and the first groove, a second resonance control layer disposed between the second anode electrode and the second groove, and a partition layer disposed between the first sub-pixel area and the second sub-pixel area by patterning the third insulating layer;
forming a first light emitting stack layer in the first groove and forming a second light emitting stack layer in the second groove; and
forming a cathode electrode on the first light emitting stack layer, the second light emitting stack layer, and the insulating layer.
